(19) United States
(12) Patent Application Publication
(10) Pub. No.: US 2024/0088626 A1
(43) Pub. Date: Mar. 14, 2024

(54) SEMICONDUCTOR LASER DEVICE

(71) Applicant: Mitsubishi Electric Corporation, Tokyo (JP)

(72) Inventor: Kimio SHIGIHARA, Tokyo (JP)

(73) Assignee: Mitsubishi Electric Corporation, Tokyo (JP)

(21) Appl. No.: 18/262,901

(22) PCT Filed: Mar. 10, 2021
(86) PCT No.: PCT/JP2021/009586

§ 371 Date: Jul. 25, 2023

(51) Int. Cl. H01S 5/22

(52) U.S. Cl. CPC H01S 5/2218

(57) ABSTRACT

A semiconductor laser device of the present disclosure includes: a first-conductivity-type cladding layer, a first-conductivity-type-side optical guide layer, an active layer, a second-conductivity-type-side optical guide layer, a second-conductivity-type cladding layer, and a second-conductivity-type contact layer, laminated above a first-conductivity-type semiconductor substrate; and a resonator having a length L_{c}. The resonator includes a current confinement region having a length L_{f} and a current injection region having a length L_{c}−L_{f}. The current confinement region includes a ridge inner region, ridge outer regions provided on both sides thereof and having current non-injection structures, and cladding regions which are provided on both sides thereof and in which at least the contact layer and the cladding layer are removed. The current injection region includes a ridge region and the cladding regions provided on both sides thereof.

### TECHNICAL FIELD

The present disclosure relates to a semiconductor laser device.

### BACKGROUND ART

A broad-area semiconductor laser device has advantages such as enabling high output.

Patent Document 1 discloses that a ridge-type broad-area semiconductor laser device having a real refractive index distribution in the horizontal direction has a guide layer that is so thick as to allow a high-order mode of a first order or higher in the lamination direction of a crystal, and terrace regions having a refractive index lower than the effective refractive index in a ridge region and higher than the refractive index in cladding regions are provided on both sides of the ridge with grooves interposed therebetween, thereby decreasing the number of modes allowed in the horizontal direction and narrowing a horizontal-direction divergence angle. Here, the real refractive index distribution refers to a refractive index distribution in which refractive indices are described by real numbers, a waveguide mechanism is a refractive index waveguide, and an electric field distribution, a magnetic field distribution, a propagation constant, and the like obtained by solving a wave equation are real numbers.

Patent Document 2 discloses that, in a ridge-type broad-area semiconductor laser device in which a ridge is buried with semiconductor layers on both sides thereof so that a refractive index difference arises in the horizontal direction, a current non-injection structure is formed on the ridge side of the boundary between the ridge and each semiconductor layer, thereby reducing peaks of near field patterns (NFP) appearing near both ends of the ridge, and the current non-injection width is preferably 10 μm or less in order to suppress increase in loss, for example.

Patent Document 3 discloses a ridge-type broad-area semiconductor laser device configured such that, in a ridge structure having a ridge width of 30 μm in which a high-order mode is allowed, protons are implanted over a depth of 1.6 μm from a ridge surface to a ridge bottom except a center part having a ridge width of 15 μm, thus forming a proton implanted region having a high resistance, and current flows in the ridge structure center part having the ridge width of 15 μm, thereby increasing the gain in a fundamental mode and selectively causing oscillation in the fundamental mode.

### CITATION LIST

### Patent Document

Patent Document 1: WO2019/053854

Patent Document 2: Japanese Laid-Open Patent Publication No. 2006-294745

Patent Document 3: Japanese Laid-Open Patent Publication No. 03-196689

### Non-Patent Document

Non-Patent Document 1: N. Yonezu, I. Sakuma, K. Kobayashi, T. Kamejima, M. Ueno, and Y. Nannichi, “A GaAs-AlxGa1-xAs Double Heterostructure Planar Stripe Laser”, Jpn. J. Appl. Phys., vol. 12, no. 10, pp. 1585-1592, 1973

Non-Patent Document 2: Kawakami, “Optical waveguides”, pp. 18-31, Asakura Publishing (1992)

Non-Patent Document 3: Iga (ed), “Semiconductor laser”, pp. 35-38, Oct. 25, 1994 (Ohmsha)

Non-Patent Document 4: G. B. Hocker and W. K. Burns, “Mode dispersion in diffused channel waveguides by the effective index method”, Appl. Opt., Vol. 16, No. 1, pp. 113-118, 1977

Non-Patent Document 5: S. Arsian et. Al., “Non-uniform longitudinal current density induced power saturation in GaAs-based high power diode laser”, Appl. Phys. Lett., Vol. 117, pp. 203506, 2020

### SUMMARY OF THE INVENTION

### Problem to be Solved by the Invention

In the conventional ridge-type broad-area semiconductor laser device having a real refractive index distribution, there is a problem that the horizontal divergence angle varies depending on the mode in which oscillation occurs among the allowed modes. This is because the gain differences among the allowed modes are small.

In addition, in the conventional ridge-type broad-area semiconductor laser device having a real refractive index distribution, unlike the broad-area semiconductor laser device buried with semiconductor layers, no peaks appear in the NFPs near both ends of the ridge, and when current is locally decreased, the NFP at that part does not weaken. This is because, in the case of the ridge-type broad-area semiconductor laser device having a real refractive index distribution, NFPs are determined by linear combination of the allowed modes, and locally decreasing current influences all the modes.

It is considered that such a peculiar phenomenon that appears in the broad-area semiconductor laser device buried with semiconductor layers occurs because a gain waveguide or a loss waveguide is formed by burying with the semiconductor layers. Therefore, such a structure buried with semiconductor layers has not so far been applied to the ridge-type broad-area semiconductor laser device having a real refractive index distribution.

Further, proton implantation for obtaining a high resistance in the conventional ridge-type broad-area semiconductor laser device is performed until reaching the ridge bottom, and therefore light emitted at an active layer spreads to the proton implanted region. Since the proton implantation destroys the crystalline state of a crystal layer, the beam spreading to the proton implanted region undergoes scattering due to a crystal defect, resulting in great loss. Thus, slope efficiency is reduced and therefore power conversion efficiency is reduced. Further, since the proton implanted region including many crystal defects is near the active layer, there is a problem that reliability of the broad-area semiconductor laser device is significantly reduced due to the crystal defects in the proton implanted region.

In addition, since the current non-injection structure based on proton implantation is provided uniformly in a resonator, operation voltage increases, thus causing a problem that power conversion efficiency is reduced.

The present disclosure has been made to solve the above problems, and an object of the present disclosure is to provide a ridge-type broad-area semiconductor laser device having a real refractive index distribution, in which the horizontal-direction divergence angle is narrowed, operation voltage increase due to providing a current non-injection structure is suppressed, and increase in scattering loss due to a crystal defect is suppressed, thereby keeping high power conversion efficiency and achieving high reliability.

### Means to Solve the Problem

A semiconductor laser device according to the present disclosure includes: a first-conductivity-type semiconductor substrate; a first-conductivity-type cladding layer, a first-conductivity-type-side optical guide layer, an active layer, a second-conductivity-type-side optical guide layer, a second-conductivity-type cladding layer, and a second-conductivity-type contact layer, which are sequentially laminated above the first-conductivity-type semiconductor substrate; and a resonator having a length L_{c} and formed of a front end surface and a rear end surface to allow a round trip of a laser beam therebetween. An oscillation wavelength is λ. The resonator includes a current confinement region having a length L_{f} and a current injection region having a length L_{c}−L_{f}. The current confinement region is composed of a ridge inner region of which a width is 2Wᵢ and an effective refractive index is nₐⁱ, ridge outer regions which are provided on both sides of the ridge inner region and of which a width is Wₒ and an effective refractive index is nₐ^{o}, the ridge outer regions having current non-injection structures, and cladding regions which are provided on both sides of the ridge outer regions and in which the second-conductivity-type contact layer and at least a part of the second-conductivity-type cladding layer are removed and an effective refractive index is n_{c}. An average refractive index nₐ^{e} of the ridge inner region and the ridge outer region is represented by the following expression:

nₐ^{e}=(nₐⁱ·Wᵢ+nₐ^{o}·Wₒ)/(Wᵢ+Wₒ). [Mathematical 1]

The following relationship is satisfied:

$$[ Mathematical 2 ]$$

$$\frac{2 π}{λ} \sqrt{{( {n}_{a}^{e} )}^{2} - {n}_{c}^{2}} ( {W}_{i} + {W}_{o} ) > \frac{π}{2} .$$

A number of modes allowed in a ridge-width direction in the current confinement region is m, m being an integer not less than 2. The width Wₒ of the ridge outer region is greater than a distance from a lower end of each current non-injection structure to the active layer. The current injection region is composed of a ridge region of which a width in the ridge-width direction is 2W and an effective refractive index is nₐ which is a real number, and the cladding regions provided on both sides of the ridge region. A number of modes allowed in the ridge-width direction in the current injection region is m which is the same as the number of modes allowed in the current confinement region. The length L_{f} of the current confinement region is greater than zero and smaller than the length L_{c} of the resonator.

### Effect of the Invention

In the semiconductor laser device according to the present disclosure, the current non-injection structures, i.e., the current confinement region is provided in a part in the resonator, and the current injection region is provided in the other part of the resonator. Thus, the gains in low-order modes become greater than the gains in high-order modes, so that laser oscillation can be caused in low-order modes and the horizontal divergence angle is narrowed, and as compared to the case where the current non-injection structures are provided over the entire resonator, the electric resistance is reduced, whereby operation voltage is reduced and power conversion efficiency is improved.

### BRIEF DESCRIPTION OF THE DRAWINGS

FIG. 1 is a schematic diagram showing a flow of current and a refractive index distribution in a cross-section of a current injection region in the present disclosure and a ridge-type broad-area semiconductor laser device having a real refractive index distribution in a comparative example.

FIG. 2 is a schematic diagram showing a flow of current and a refractive index distribution in a cross-section of a current confinement region in a ridge-type broad-area semiconductor laser device having a real refractive index distribution according to the present disclosure.

FIG. 3 is a perspective view and a sectional view showing a ridge-type broad-area semiconductor laser device in 975 nm band having a real refractive index distribution according to embodiment 1.

FIG. 4 shows the gain in each mode of the ridge-type broad-area semiconductor laser device in 975 nm band having a real refractive index distribution according to embodiment 1.

FIG. 5 shows the gain in each mode of the ridge-type broad-area semiconductor laser device in 975 nm band having a real refractive index distribution according to embodiment 1.

FIG. 6 shows the gain in each mode of the ridge-type broad-area semiconductor laser device in 975 nm band having a real refractive index distribution according to embodiment 1.

FIG. 7 is a perspective view and a sectional view showing a ridge-type broad-area semiconductor laser device in 975 nm band having a real refractive index distribution according to embodiment 2.

FIG. 8 shows the gain in each mode of the ridge-type broad-area semiconductor laser device in 975 nm band having a real refractive index distribution according to embodiment 2.

FIG. 9 shows the gain in each mode of the ridge-type broad-area semiconductor laser device in 975 nm band having a real refractive index distribution according to embodiment 2.

FIG. 10 shows the gain in each mode of the ridge-type broad-area semiconductor laser device in 975 nm band having a real refractive index distribution according to embodiment 2.

FIG. 11 is a perspective view and a sectional view showing a ridge-type broad-area semiconductor laser device in 975 nm band having a real refractive index distribution according to embodiment 3.

FIG. 12 shows the gain in each mode of the ridge-type broad-area semiconductor laser device in 975 nm band having a real refractive index distribution according to embodiment 3.

FIG. 13 shows the gain in each mode of the ridge-type broad-area semiconductor laser device in 975 nm band having a real refractive index distribution according to embodiment 3.

FIG. 14 shows the gain in each mode of the ridge-type broad-area semiconductor laser device in 975 nm band having a real refractive index distribution according to embodiment 3.

FIG. 15 is a perspective view and a sectional view showing a ridge-type broad-area semiconductor laser device in 975 nm band having a real refractive index distribution according to embodiment 4.

FIG. 16 is a perspective view and a sectional view showing a ridge-type broad-area semiconductor laser device in 975 nm band having a real refractive index distribution according to embodiment 5.

FIG. 17 is a perspective view and a sectional view showing a ridge-type broad-area semiconductor laser device in 975 nm band having a real refractive index distribution according to embodiment 6.

### DESCRIPTION OF EMBODIMENTS

### Embodiment 1

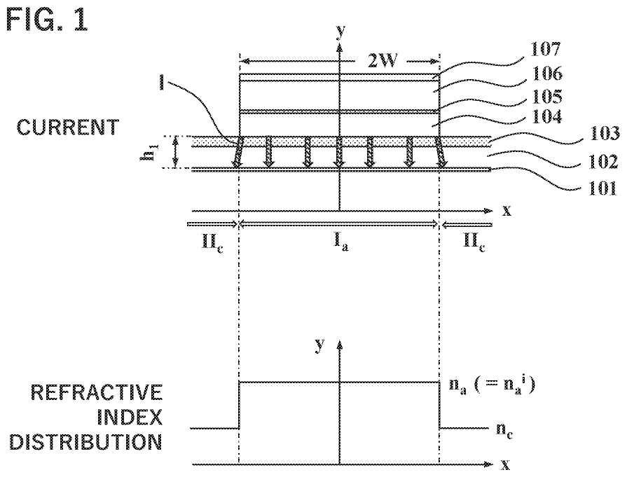

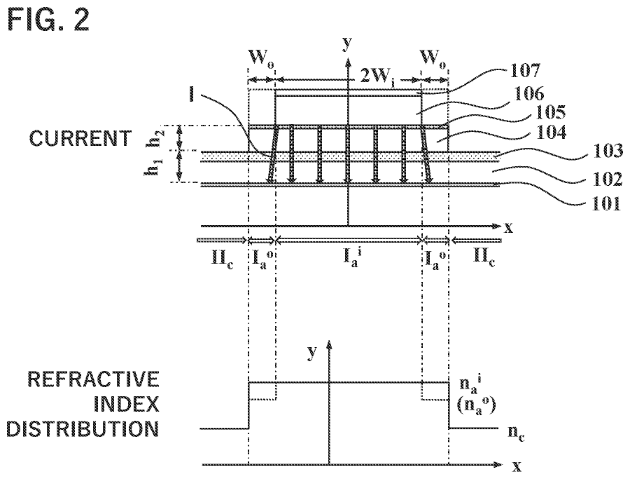

First, difference between ridge-type broad-area semiconductor laser devices in the present disclosure and a comparative example will be described with reference to FIG. 1 and FIG. 2. FIG. 1 is a schematic diagram showing a flow of current and a refractive index distribution in a cross-section of a current injection region in the ridge-type broad-area semiconductor laser device in the present disclosure and the ridge-type broad-area semiconductor laser device having a real refractive index distribution in the comparative example. FIG. 2 is a schematic diagram showing a flow of current and a refractive index distribution in a cross-section of a current confinement region in the ridge-type broad-area semiconductor laser device having a real refractive index distribution according to the present disclosure.

In FIG. 1, from a semiconductor substrate (not shown) side on the lower side, the following layers are shown: an active layer 101, a guide layer 102, a first etching stop layer 103 (first ESL layer (etching stop layer: ESL)), a p-type first cladding layer 104, a second etching stop layer 105 (second ESL layer), a p-type second cladding layer 106, and a p-type contact layer 107.

The distance from the upper end of the first ESL layer 103 to the upper end of the active layer 101 is denoted by h₁. Current I flowing in a ridge region (Iₐ) flows while spreading also in the horizontal direction (x-axis direction) from the upper end of the first ESL layer 103. A current distribution J(x) at the upper end of the active layer 101 can be calculated using Non-Patent Document 1. The x-axis direction may be referred to as ridge-width direction.

The ridge region (Iₐ) having a ridge region width 2W has a structure sandwiched between cladding regions (II_{c}). The effective refractive indices in the ridge region (Iₐ) and the cladding regions (II_{c}) are respectively denoted by nₐ and n_{c}. According to Non-Patent Document 2, a normalized frequency v can be defined as shown by the following Expression (1).

$$\begin{matrix}[ Mathematical 3 ] & \\ v ≡ \frac{2 π}{λ} \sqrt{{n}_{a}^{2} - {n}_{c}^{2}} W & ( 1 )\end{matrix}$$

Here, λ is the oscillation wavelength of the semiconductor laser. A value INT[v/(π/2)]+1 which is obtained by dividing the normalized frequency v by π/2, making the resultant value into an integer, and then adding 1 thereto, is the number of modes allowed in the x direction.

FIG. 2 is a schematic diagram showing a flow of current I and a refractive index distribution in a cross-section perpendicular to the optical wave-guiding direction in a current confinement region (Cₙ) having current non-injection structures, in the ridge-type broad-area semiconductor laser device having a real refractive index distribution according to the present disclosure.

In this structure, parts from the p-type contact layer 107 at the top surface to the upper end of the second ESL layer 105 are removed by etching in such a range that the effective refractive index in ridge outer regions (Iₐ^{o}) having a width Wₒ (hereinafter, referred to as ridge outer region width) is substantially the same as the effective refractive index in a ridge inner region (Iₐⁱ) having a width 2Wᵢ (hereinafter, referred to as ridge inner region width).

The above-described state in which the effective refractive indices are substantially the same means that, where the effective refractive index in the ridge inner region (Iₐⁱ) is denoted by nₐⁱand the effective refractive index in the ridge outer regions (Iₐ^{o}) is denoted by nₐ^{o}, the number of allowed modes calculated by substituting an average refractive index nₐ^{e} calculated by the following Expression (2) into nₐ in Expression (1) is the same as the number of allowed modes in a case where there are no ridge outer regions (Iₐ^{o}) (Wₒ=0).

[Mathematical 4]

nₐ^{e}=(nₐⁱ·Wᵢ+nₐ^{o}·Wₒ)/(Wᵢ+Wₒ) (2)

The upper parts in the ridge outer regions (Iₐ^{o}) are removed by etching until reaching the upper end of the second ESL layer 105 and then are coated with insulation films (not shown), so that the current I mainly flows in the ridge inner region (Iₐⁱ). The distance from the upper end of the first ESL layer 103 to the upper end of the second ESL layer 105 is denoted by h2. The current I begins to spread also in the horizontal direction from the upper end of the second ESL layer 105, thus reaching the active layer 101 through a distance h₁+h₂. The distance h₁+h₂ through which the current I spreads is greater than the distance h₁ through which the current I spreads in the structure in the comparative example, but since the current is injected only in the ridge inner region (Iₐⁱ), the current spread range at the active layer position is narrower in the structure of the present disclosure.

Meanwhile, in the ridge-type broad-area semiconductor laser device according to the present disclosure, in the region where the current non-injection structures are not provided, i.e., a current injection region (Cᵢ), the current spreads in the horizontal (x) direction from the upper end of the first ESL layer 103, as in the structure in the comparative example shown in FIG. 1.

An ith-order mode allowed in the horizontal direction is denoted by φᵢ(x), and normalization is performed as shown by the following Expression (3). The allowed mode φᵢ(x) can be calculated from Non-Patent Document 2 or the like.

[Mathematical 5]

∫_{-∞}^{∞}ϕᵢ(x)²dx=3 (3)

Meanwhile, in a case where current of 1 ampere (A) flows in a semiconductor laser device having a ridge-width-direction element width W_{ch} and a resonator length L_{c}, normalization is performed as shown by the following Expression (4).

[Mathematical 6]

W_{ch}· [symbol] _{c}∫_{-∞}^{∞}J(x)dc=1 (4)

Where there is a current confinement region (Cₙ) having a length L_{f} in the resonator, a gain Gᵢ when a beam makes one round trip in the resonator is defined as shown by the following Expression (5). Since the optical intensity distribution (mode) and the current distribution are both normalized, the difference between the gains in the respective modes can be found from the magnitude relationship of the gain Gᵢ.

[Mathematical 7]

Gᵢ=2L_{f}∫_{-∞}^{∞}ϕᵢ(x)dc+2(L_{c}=L_{f}) ∫_{-∞}^{∞}ϕᵢ(x)²J(x)dx (5)

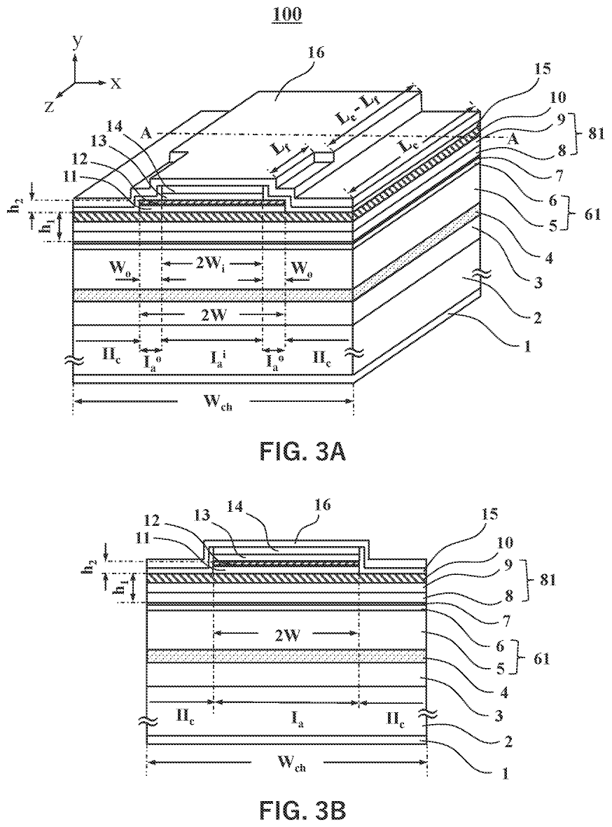

FIG. 3A is a perspective view showing a ridge-type broad-area semiconductor laser device 100 in 975 nm band having a real refractive index distribution according to embodiment 1. FIG. 3B is a sectional view of the current injection region (Cᵢ) in the ridge-type broad-area semiconductor laser device 100, i.e., a sectional view along line A-A in FIG. 3A.

In FIG. 3A, an xyz orthogonal coordinate system is defined, for convenience of description. An x axis is an axis perpendicular to a yz plane and coincides with an axis in the width direction of the ridge-type broad-area semiconductor laser device 100. As described above, the x-axis direction may be referred to as “ridge-width direction”. Along the x axis, a horizontal transverse mode occurs in the ridge-type broad-area semiconductor laser device 100. A y-axis direction coincides with the crystal growth direction of semiconductor layers formed above an n-type GaAs substrate 2. The y-axis direction may be referred to as “lamination direction”. The y axis is parallel to a normal to the upper surface of the n-type GaAs substrate 2.

A z axis is the direction in which a laser beam of the ridge-type broad-area semiconductor laser device 100 is emitted, and is also a length-direction axis of a resonator that the ridge-type broad-area semiconductor laser device 100 has. The z direction may be referred to as “resonator direction”. The above-described definition about the orthogonal coordinate system is applied in the same manner also to perspective views of ridge-type broad-area semiconductor laser devices in other embodiments described later.

As shown in FIG. 3A, the ridge-type broad-area semiconductor laser device 100 is composed of, from the lower surface side (may be referred to as back surface side), an n-type electrode 1 (first-conductivity-type electrode), the n-type GaAs substrate 2 (first-conductivity-type semiconductor substrate), an n-type AlGaAs cladding layer 3 (first-conductivity-type cladding layer, refractive index n_{cn}) having an Al composition ratio of 0.20 and a layer thickness of 1.5 μm, an n-type AlGaAs low-refractive-index layer 4 (refractive index nₗₙ) having an Al composition ratio of 0.25 and a layer thickness dₗₙ of 200 nm, an n-side AlGaAs second optical guide layer 5 (refractive index n_{g2n}) having an Al composition ratio of 0.16 and a layer thickness dg₂ₙ of 1050 nm, an n-side AlGaAs first optical guide layer 6 (refractive index ngln) having an Al composition ratio of 0.14 and a layer thickness d_{g1n} of 100 nm, an InGaAs quantum well active layer 7 (refractive index nₐₘ ) having an In composition ratio of 0.119 and a layer thickness dₐₘ of 8 nm, a p-side AlGaAs first optical guide layer 8 (refractive index n_{g1p}) having an Al composition ratio of 0.14 and a layer thickness d_{g1p} of 350 nm, a p-side AlGaAs second optical guide layer 9 (refractive index n_{g2p}) having an Al composition ratio of 0.16 and a layer thickness d_{g2p} of 300 nm, a p-type AlGaAs first etching stop layer 10 (which may be referred to as p-type AlGaAs first ESL layer, p-type AlGaAs low-refractive-index layer, or second-conductivity-type low-refractive-index layer; refractive index nₗₚ) having an Al composition ratio of 0.55 and a layer thickness dₗₚ of 80 nm, a p-type AlGaAs first cladding layer 11 (second-conductivity-type first cladding layer, refractive index n_{cp}) having an Al composition ratio of 0.20 and a layer thickness of 0.50 μm, a p-type AlGaAs second etching stop layer 12 (p-type AlGaAs second ESL layer 12) having an Al composition ratio of 0.55 and a layer thickness of 40 nm, a p-type AlGaAs second cladding layer 13 (second-conductivity-type second cladding layer) having an Al composition ratio of 0.20 and a layer thickness of 0.96 μm, a p-type GaAs contact layer 14 (second-conductivity-type contact layer) having a layer thickness of 0.2 μm, SiN insulation films 15 having a film thickness of 0.2 μm, and a p-type electrode 16 (second-conductivity-type electrode) on the upper surface side.

The n-side AlGaAs second optical guide layer 5 and the n-side AlGaAs first optical guide layer 6 are collectively referred to as n-side optical guide layer 61 or a first-conductivity-type-side optical guide layer 61, and the p-side AlGaAs first optical guide layer 8 and the p-side

AlGaAs second optical guide layer 9 are collectively referred to as p-side optical guide layer 81 or second-conductivity-type-side optical guide layer 81. Each optical guide layer is normally a layer that is not doped, and therefore on which side of the InGaAs quantum well active layer 7 each optical guide layer is present is distinguished by indicating “side”. That is, the n side or the first conductivity type side refers to the side where each n-type or first-conductivity-type layer is present with respect to the InGaAs quantum well active layer 7. Similarly, the p side or the second conductivity type side refers to the side where each p-type or second-conductivity-type layer is present with respect to the InGaAs quantum well active layer 7.

The second-conductivity-type first cladding layer 11 (p-type AlGaAs first cladding layer 11) and the second-conductivity-type second cladding layer 13 (p-type AlGaAs second cladding layer 13) are collectively referred to as second-conductivity-type cladding layer.

Such setting that the In composition ratio of the InGaAs quantum well active layer 7 is 0.119 and the layer thickness thereof is 8 nm is for making the oscillation wavelength be substantially 975 nm.

A front end surface and a rear end surface forming a resonator that allows round trip of a laser beam are provided at both ends of the ridge-type broad-area semiconductor laser device 100 by cleavage or the like, for example.

First, the feature of the structure of the ridge-type broad-area semiconductor laser device 100 according to embodiment 1 will be described.

The ridge-type broad-area semiconductor laser device 100 according to embodiment 1 includes: the first-conductivity-type semiconductor substrate 2; the first-conductivity-type cladding layer 3, the first-conductivity-type-side optical guide layer 61, the quantum well active layer 7, the second-conductivity-type-side optical guide layer 81, the second-conductivity-type cladding layer formed of the second-conductivity-type first cladding layer 11 and the second-conductivity-type second cladding layer 13, and the second-conductivity-type contact layer 14, which are sequentially laminated above the first-conductivity-type semiconductor substrate 2; and the resonator having a length L_{c} and formed of a front end surface and a rear end surface to allow a round trip of a laser beam therebetween. An oscillation wavelength is λ, and the resonator includes a current confinement region (Cₙ) having a length L_{f} and a current injection region (Cᵢ) having a length L_{c}−L_{f}.

The current confinement region (Cₙ) having the length L_{f} is composed of the ridge inner region (Iₐⁱ) of which the width is the ridge inner region width 2Wᵢ and the effective refractive index is nₐⁱ, the ridge outer regions (Iₐ^{o}) which are provided on both sides of the ridge inner region (Iₐⁱ) and of which the width is the ridge outer region width Wₒ and the effective refractive index is nₐ^{o}, the ridge outer regions (Iₐ^{o}) having current non-injection structures, and the cladding regions (II_{c}) which are provided on both sides of the ridge outer regions (Iₐ^{o}) and in which the second-conductivity-type contact layer 14 and the second-conductivity-type cladding layer are removed and the effective refractive index is n_{c}.

The average refractive index nₐ^{e} of the ridge inner region (Iₐⁱ) and the ridge outer region (Iₐ^{o}) is represented by the above Expression (1), and the normalized frequency V_{nc} in the current confinement region (Cₙ) satisfies the following Expression (6).

$$\begin{matrix}[ Mathematical 8 ] & \\ {V}_{nc} ≡ \frac{2 π}{λ} \sqrt{{( {n}_{a}^{e} )}^{2} - {n}_{c}^{2}} ( {W}_{i} + {W}_{o} ) > \frac{π}{2} & ( 6 )\end{matrix}$$

The ridge outer region width Wₒ of each ridge outer region (Iₐ^{o}) is greater than the distance from the lower end of the current non-injection structure to the quantum well active layer 7 and is smaller than the width W which is 1/2 of the ridge region width. The height from the upper end of each cladding region (II_{c}) to the lower end of the current non-injection structure is such a height that the effective refractive index nₐ^{o} in the ridge outer regions (Iₐ^{o}) and the effective refractive index nₐⁱin the ridge inner region (Iₐⁱ) are substantially the same.

Meanwhile, as shown in the perspective view in FIG. 3A and the sectional view in FIG. 3B, the current injection region (Cᵢ) having the length L_{c}−L_{f} in the resonator direction is formed in a region having the length L_{c}−L_{f} in the resonator and is composed of the ridge region (Iₐ) which has a current injection structure and of which the ridge region width is 2W and the effective refractive index is a real number na, and the cladding regions (II_{c}) which are provided on both sides of the ridge region (Iₐ) and in which the second-conductivity-type contact layer 14 and the second-conductivity-type cladding layer are removed and the effective refractive index is a real number n_{c}. A normalized frequency V_{ic} in the current injection region (Cᵢ) satisfies the following Expression (7).

$$\begin{matrix}[ Mathematical 9 ] & \\ {V}_{ì c} ≡ \frac{2 π}{λ} \sqrt{{n}_{a}^{2} - {n}_{c}^{2}} W > \frac{π}{2} & ( 7 )\end{matrix}$$

Here, the state in which the effective refractive

indexes are substantially the same means that, where the effective refractive index in the ridge inner region (Iₐⁱ) in the current confinement region (Cₙ) is nₐⁱand the effective refractive index in the ridge outer regions (Iₐ^{o}) is nₐ^{o}, the number of allowed modes calculated from Expression (2) and Expression (6) is the same as the number of allowed modes calculated from Expression (7) in a case where there are no ridge outer regions (Iₐ^{o}), i.e., a case where the ridge outer region width Wₒ is zero. This means satisfying the following Expression (8).

[Mathematical 10]

INT[V_{ic}/(π/2)]+1=INT[V_{nc}/(π/2)]+1 (8)

Where the number of modes allowed in the ridge-width direction in the current confinement region (Cₙ) is denoted by m, m becomes an integer not less than 2.

The feature of the structure of the ridge-type broad-area semiconductor laser device 100 according to embodiment 1 is as described above.

A manufacturing method for the ridge-type broad-area semiconductor laser device 100 according to embodiment 1 will be described below.

Above the n-type GaAs substrate 2, the semiconductor layers from the n-type AlGaAs cladding layer 3 to the p-type GaAs contact layer 14 are sequentially crystal-grown by a crystal growth method such as metal organic chemical vapor deposition (MOCVD).

Next, the ridge inner region (Iₐⁱ) in the current confinement region (Cₙ) having the length L_{f} and the ridge region (Iₐ) in the current injection region (Cᵢ) having the length L_{c}−L_{f} are coated with a resist and dry etching is performed until reaching the second ESL layer 12. Then, the resist is removed.

Subsequently, the ridge inner region (Iₐⁱ) and the ridge outer regions (2Iₐ^{o}) in the current confinement region (Cₙ) having the length L_{f} and the ridge region (Iₐ) in the current injection region (Cᵢ) having the length L_{c}−L_{f} are coated with a resist, dry etching is performed until reaching the p-type AlGaAs first ESL layer 10, and the resist is removed.

The ridge inner region (Iₐⁱ) in the current confinement region (Cₙ) having the length L_{f} and the ridge region (Iₐ) in the current injection region (Cᵢ) having the length L_{c}−L_{f} are coated with a resist, the SiN insulation films 15 are formed, lift-off is performed, and the resist is removed.

Further, the p-type electrode 16 and the n-type electrode 1 are formed on the upper surface side and the lower surface side, respectively.

In the ridge-type broad-area semiconductor laser device 100 according to embodiment 1, the p-type GaAs contact layer 14 and the p-type AlGaAs second cladding layer 13 in the ridge outer regions (Iₐ^{o}) in the current confinement region (Cₙ) are removed by etching, and the exposed surfaces on which removal has been performed by etching are covered with the SiN insulation films 15, thereby forming current non-injection structures. Thus, current injected in the ridge-type broad-area semiconductor laser device 100 mainly flows in the ridge inner region (Iₐⁱ).

Effects obtained by the structure characteristic of the ridge-type broad-area semiconductor laser device 100 according to embodiment 1 will be described in detail below. For example, using a refractive index and a calculation method therefor described in Iga (ed),

“Semiconductor laser”, pp. 35-38 (Non-Patent Document 3), the refractive indices of the AlGaAs layers having the Al composition ratios of 0.14, 0.16, 0.20, 0.25, and 0.55 at a wavelength of 975 nm are 3.432173, 3.419578, 3.394762, 3.364330, and 3.191285, respectively.

In addition, experientially, the refractive indices of InGaAs forming the InGaAs quantum well active layer 7 with the In composition ratio of 0.119 and SiN forming the SiN insulation films 15 are 3.542393 and 2.00, respectively.

First, the ridge structure in the case where the ridge outer region width Wₒ is zero, i.e., the ridge structure in the current injection region (Cᵢ), is assumed.

In the case where the ridge outer region width Wₒ is zero, the effective refractive index nₐ in the ridge region (Iₐ) and the effective refractive index n_{c} in the cladding regions (II_{c}) can be calculated by an equivalent refractive index method described in Non-Patent Document 4, for example, and thus are 3.41773 and 3.41723, respectively.

In a case where the ridge region width 2W of the ridge region (Iₐ) is 100 μm, a value v/(π/2) obtained by dividing the normalized frequency v in Expression (1) by π/2 is 11.991 and thus twelve modes from a zeroth order (fundamental mode) to an eleventh order are allowed.

In the case where the ridge outer region width Wₒ is zero, current spreads from the position of the first ESL layer 10 in ±x directions starting from both ends of the ridge region width 2W and passes through the distance h₁ (0.73 μm) from the first ESL layer 10 to the quantum well active layer 7, thus reaching the quantum well active layer 7.

Next, it is assumed that, over the entire resonator length L_{c} (L_{c}=4 mm), for example, parts in the ridge outer region width Wₒ=12 μm are removed by etching until reaching the upper end of the second ESL layer 12, to form current non-injection structures. This is a case where the entire resonator is formed as the current confinement region (Cₙ) in the ridge-type broad-area semiconductor laser device 100.

The effective refractive index of the above current non-injection structures is 3.41773. Thus, irrespective of removal by etching, the refractive index in the ridge region (ridge inner region (Iₐⁱ) and ridge outer regions (Iₐ^{o})) has the same value as in the case of not performing etching, and as a matter of course, satisfies the condition for being substantially the same in Expression (8). Therefore, the number of allowed modes is also the same.

Meanwhile, current injected from the p-type GaAs contact layer 14 spreads from the upper end of the second ESL layer 12 also in the +x directions starting from both ends of the ridge inner region width 2Wᵢ of the ridge inner region (Iₐⁱ). That is, current spreads in the tx directions through the distance h₁ (0.73 μm) from the upper end of the quantum well active layer 7 to the upper end of the first ESL layer 10 and the distance h₂ (0.54 μm) from the upper end of the first ESL layer 10 to the upper end of the second ESL layer 12, thus reaching the quantum well active layer 7.

Hereinafter, for simplification, a resistivity p in a range from the part where the current begins to spread in the tx direction to the quantum well active layer 7 is assumed to be 0.35 Ωcm. It has already been confirmed that the tendency of the gain Gi is the same even if the value of the resistivity ρ is changed.

As an example, it is assumed that, in a length L_{f}=1 mm in the resonator and the ridge outer region width Wₒ=12 μm, parts from the upper surface of the p-type GaAs contact layer 14 to the upper end of the second ESL layer 12 are removed by etching, to form current non-injection structures, thus providing the current confinement region (Cₙ) having the length L_{f}=1 mm. Here, the effective refractive index of the current non-injection structures is 3.41773, and therefore the number of allowed modes does not change.

In the current confinement region (Cₙ) having the current non-injection structures, current spreads from the upper end of the second ESL layer 12 starting from both ends of the ridge inner region width 2Wᵢ of the ridge inner region (Iₐⁱ) and passes through the distance h₂ (0.54 μm) from the upper end of the second ESL layer 12 to the upper end of the first ESL layer 10 and the distance h₁ (0.73 μm) from the upper end of the first ESL layer 10 to the upper end of the quantum well active layer 7, thus reaching the quantum well active layer 7.

Meanwhile, in the remaining current injection region (Cᵢ; length: L_{c}−L_{f}=3 mm) in the resonator, as shown in FIG. 3B, current spreads from the upper end of the first ESL layer 10 starting from both ends of the ridge region width 2W.

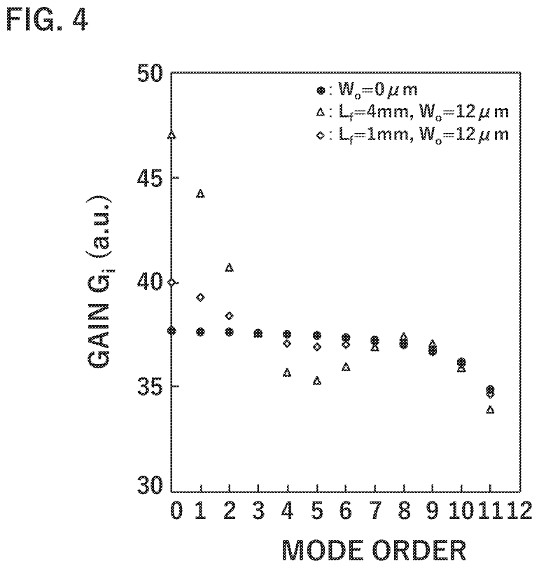

FIG. 4 shows the gain Gᵢ in each mode in the case where there are no current non-injection structures over the entire resonator (Wₒ=0 μm), the case where the current non-injection structures are provided over the entire resonator (L_{f}=L_{c}=4 mm, Wₒ=12 μm), and the case where the current non-injection structures are provided in a part in the resonator (L_{f}=1 mm, Wₒ=12 μm), i.e., the current confinement region (Cₙ) having the length L_{f}=1 mm is provided, by black circle marks, white triangular marks, and rhombus marks, respectively.

In the case where there are no current non-injection structures over the entire resonator (Wₒ=0 μm, black circle marks in FIG. 4), it is found that there is almost no gain difference among the modes. In particular, in mode orders not higher than 9, the tendency in which there is no gain difference among the modes is remarkable.

In the case where the current non-injection structures of which the length is 1 mm and the ridge outer region width Wₒ is 12 μm are provided, i.e., the current confinement region (Cₙ) having the length L_{f}=1 mm is provided (rhombus marks in FIG. 4), gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 12 μm are provided over the entire resonator length L_{c} (L_{c}=4 mm) (white triangular marks in FIG. 4), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where there are no current non-injection structures (Wₒ=0 μm), the case where the current non-injection structures are provided over the entire resonator (L_{f}=L_{c}=4 mm, Wₒ=12 μm), and the case where the current non-injection structures are provided in a part in the resonator (L_{f}=1 mm, Wₒ=12 μm), i.e., the current confinement region (Cₙ) having the length L_{f}=1 mm is provided, operation voltages are calculated to be 1.518 V, 1.552 V, and 1.525 V, respectively, and power conversion efficiencies when the beam output is 5 W are 63.4%, 62.0%, and 63.1%, respectively.

In the case where the current confinement region (Cₙ) as described above is provided in the ridge-type broad-area semiconductor laser device 100 according to embodiment 1, as compared to the case where there are no current non-injection structures over the entire resonator, gain differences among the modes become greater and the gains Gᵢ in low-order modes (zeroth to second orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 100 according to embodiment 1, the current injection area becomes smaller as compared to the case where there is no current confinement region (Cₙ) at all. Thus, in the ridge-type broad-area semiconductor laser device 100 according to embodiment 1, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger in the case where the current confinement region (Cₙ) as described above is provided. This means that the electric resistance is reduced. Thus, an effect that operation voltage is reduced and power conversion efficiency is improved is provided.

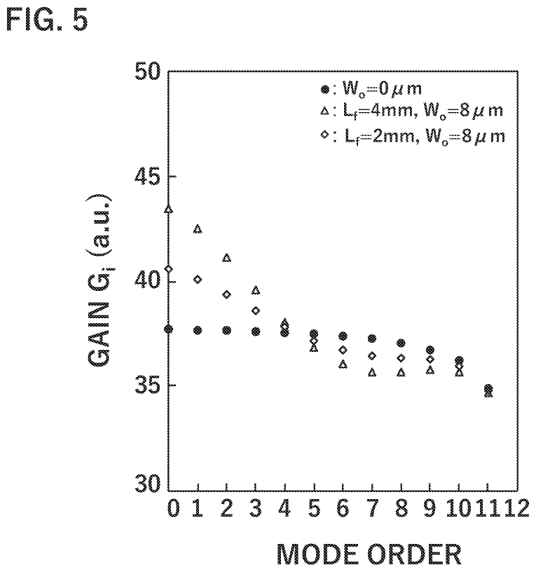

FIG. 5 shows the gain Gᵢ in each mode in the case where the current non-injection structures are provided over the entire resonator (L_{f}=L_{c}=4 mm, Wₒ=8 μm) and the case where the current non-injection structures are provided in a part in the resonator (L_{f}=2 mm, Wₒ=8 μm), i.e., the current confinement region (Cₙ) having the length L_{f}=2 mm is provided, by white triangular marks and rhombus marks, respectively. In addition, for comparison, the gain Gᵢ in each mode in the case where there are no current non-injection structures over the entire resonator (Wₒ=0 μm) is shown by black circle marks.

In the case where the current non-injection structures (L_{f}=2 mm, Wₒ=8 μm), i.e., the current confinement region (Cₙ) having the length L_{f}=2 mm is provided in a part in the resonator, gain differences arise among the modes and the gains Gᵢ in low-order modes of zeroth to fourth orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 8 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=8 μm) and the case where the current non-injection structures are provided in a part in the resonator (L_{f}=2 mm, Wₒ=8 μm), i.e., the current confinement region (Cₙ) having the length L_{f}=2 mm is provided, operation voltages are calculated to be 1.538 V and 1.527 V, respectively, and power conversion efficiencies when the beam output is 5 W are 62.5% and 63.0%, respectively.

In the case where the current confinement region (Cₙ) as described above is provided in the ridge-type broad-area semiconductor laser device 100 according to embodiment 1, as compared to the case where there are no current non-injection structures over the entire resonator, gain differences among the modes become greater and the gains Gᵢ in low-order modes (zeroth to fourth orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 100 according to embodiment 1, the current injection area becomes smaller as compared to the case where there is no current confinement region (Cₙ) at all. Thus, in the ridge-type broad-area semiconductor laser device 100 according to embodiment 1, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger in the case where the current confinement region (Cₙ) as described above is provided. This means that the electric resistance is reduced. Thus, an effect that operation voltage is reduced and power conversion efficiency is improved is provided.

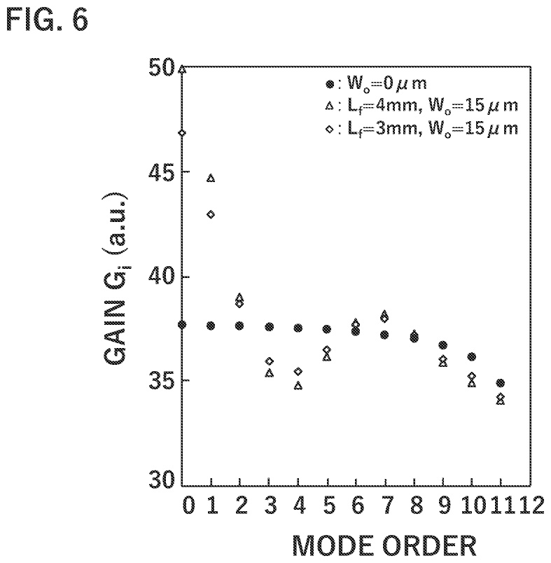

FIG. 6 shows the gain Gᵢ in each mode in the case where the current non-injection structures are provided over the entire resonator (L_{f}=L_{c}=4 mm, Wₒ=15 μm) and the case where the current non-injection structures are provided in a part in the resonator (L_{f}=3mm, Wₒ=15 μm), i.e., the current confinement region (Cₙ) having the length L_{f}=3 mm is provided, by white triangular marks and rhombus marks, respectively. In addition, for comparison, the gain Gᵢ in each mode in the case where there are no current non-injection structures over the entire resonator (Wₒ=0 μm) is shown by black circle marks.

In the case where the current non-injection structures (L_{f}=3 mm, Wₒ=15 μm), i.e., the current confinement region (Cₙ) having the length L_{f}=3 mm is provided in a part in the resonator, gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 15 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=15 μm) and the case where the current non-injection structures are provided in a part in the resonator (L_{f}=3 mm, Wₒ=15 μm), i.e., the current confinement region (Cₙ) having the length L_{f}=3 mm is provided, operation voltages are calculated to be 1.564 V and 1.549 V, respectively, and power conversion efficiencies when the beam output is 5 W are 61.5% and 62.1%, respectively.

In the case where the current confinement region (Cₙ) as described above is provided in the ridge-type broad-area semiconductor laser device 100 according to embodiment 1, as compared to the case where there are no current non-injection structures over the entire resonator, gain differences among the modes become greater and the gains Gᵢ in low-order modes (zeroth to second orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 100 according to embodiment 1, the current injection area becomes smaller as compared to the case where there is no current confinement region (Cₙ) at all. Thus, in the ridge-type broad-area semiconductor laser device 100 according to embodiment 1, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger in the case where the current confinement region (Cₙ) as described above is provided. This means that the electric resistance is reduced. Thus, an effect that operation voltage is reduced and power conversion efficiency is improved is provided.

As described above, in the case where the current non-injection structures, i.e., the current confinement region (Cₙ) is provided in a part in the resonator, irrespective of the length of the current confinement region (Cₙ) or the value of the ridge outer region width Wo, gain differences can be provided among allowed modes and the gains Gᵢ in low-order modes can be made greater than the gains Gᵢ in high-order modes, as compared to the case where the current confinement region (Cₙ) is not provided. Thus, laser oscillation is reached in low-order modes and the horizontal divergence angle is narrowed. In addition, since loss does not change depending on whether or not the current confinement region (Cₙ) is present, oscillation occurs with a smaller gain Gᵢ and threshold current is reduced. Further, the ridge-type broad-area semiconductor

laser device 100 according to embodiment 1 provides an effect that operation voltage is reduced and power conversion efficiency is improved, as compared to the case where the current non-injection structures are provided over the entire resonator.

In the case where the n-type AlGaAs low-refractive-index layer 4 (layer thickness dₗₙ, refractive index nₗₙ) is interposed between the n-type AlGaAs cladding layer 3 (refractive index n_{cn}) and the n-side optical guide layer 61, and the p-type AlGaAs low-refractive-index layer 10 (layer thickness dₗₚ, refractive index nₗₚ) is interposed between the p-type AlGaAs first cladding layer 11 (refractive index n_{cp}) and the p-side optical guide layer 81, a magnitude relationship between uₚ and uₙ is represented by the following Expression (9), instead of Expression (1).

$$\begin{matrix}[ Mathematical 11 ] & \\ {u}_{n} = \frac{2 π}{λ} \sqrt{{n}_{cn}^{2} - {n}_{in}^{2}} \frac{{d}_{in}}{2} & ( 9 )\end{matrix}$$

$${u}_{p} = \frac{2 π}{λ} \sqrt{{n}_{cp}^{2} - {n}_{ip}^{2}} \frac{{d}_{ip}}{2}$$

$${u}_{p} > {u}_{n}$$

In the ridge-type broad-area semiconductor laser device 100 according to embodiment 1, uₙ is 0.29227 and uₚ is 0.29840. Therefore, uₙ<uₚ is satisfied, and an optical intensity distribution in the y direction, i.e., the lamination direction, is displaced to the n-type GaAs substrate 2 side, thus forming a structure in which the number of built-in allowed modes in the x direction, i.e., the ridge-width direction, is decreased.

For example, if the layer thickness of the p-type AlGaAs low-refractive-index layer 10 is increased from 80 nm to 140 nm, uₚ increases to 0.52221, and the optical intensity distribution can be further displaced to the n-type GaAs substrate 2 side, whereby the number of built-in allowed modes can be further decreased. By decreasing the number of built-in allowed modes in advance as described above, oscillation in low-order modes can be easily caused.

In the ridge-type broad-area semiconductor laser device 100 according to embodiment 1, the n-type AlGaAs low-refractive-index layer 4 is provided between the n-type AlGaAs cladding layer 3 and the n-side optical guide layer 61, and the p-type AlGaAs low-refractive-index layer 10 is provided between the p-type AlGaAs first cladding layer 11 and the p-side optical guide layer 81. However, the n-type

AlGaAs low-refractive-index layer 4 may be provided in the n-type AlGaAs cladding layer 3, and the p-type AlGaAs low-refractive-index layer 10 may be provided in the p-type AlGaAs first cladding layer 11. In this case, while the p-type AlGaAs first cladding layer 11 on the upper side of the first ESL layer 10 is removed by etching, the p-type AlGaAs first cladding layer 11 on the lower side of the first ESL layer 10 is left, thus contributing to spread of current.

As a method for decreasing the number of built-in allowed modes by displacing the optical intensity distribution in the resonator to the n-type GaAs substrate 2 side, other than the above method, the refractive index nip of the p-type AlGaAs low-refractive-index layer 10 may be reduced, or the refractive index n_{cn} of the n-type AlGaAs cladding layer 3 may be made greater than the refractive index n_{cp} of the p-type AlGaAs first cladding layer 11 or the refractive index of the p-type AlGaAs second cladding layer 13, for example.

In the ridge-type broad-area semiconductor laser device 100 according to embodiment 1, the total optical guide layer thickness of the p-side optical guide layer 81 and the n-side optical guide layer 61 is as great as 1.8 μm, and therefore in this waveguide structure, a plurality of modes are allowed also in the lamination direction (y direction), as shown below.

First, d_{gy}^{m} (=d_{g2n}+d_{g1n}+dₐₘ+d_{g1p}+d_{g2p}) which is the sum of the layer thicknesses of the optical guide layers including the quantum well active layer 7 is 1.808 μm.

Then, an average refractive index n_{gy}^{m} of the optical guide layers including the quantum well active layer 7 is represented as shown by the following Expression (11), and the value thereof is 3.423256. Of the refractive index n_{cn} of the n-type AlGaAs cladding layer 3 and the refractive index n_{cp} of the p-type AlGaAs first cladding layer 11, the higher refractive index is denoted by nch. In embodiment 1, the Al composition ratios of the n-type AlGaAs cladding layer 3 and the p-type AlGaAs first cladding layer 11 are the same value of 0.20, and therefore the refractive index non and the refractive index n_{cp} are the same value. That is, the refractive index n_{ch} becomes 3.394762.

$$\begin{matrix}[ Mathematical 12 ] & \\ {d}_{gy}^{m} = {d}_{g 2 n} + {d}_{g 1 n} + {d}_{am} + {d}_{g 1 p} + {d}_{2 p} & ( 10 )\end{matrix}$$

$${n}_{gy}^{m} = \frac{\begin{matrix}{n}_{g 2 n} \cdot {d}_{g 2 n} + {n}_{g 1 n} \cdot {d}_{g 1 n} + {n}_{am} \cdot \\ {d}_{am} + {n}_{g 1 p} \cdot {d}_{g 1 p} + {n}_{g 2 p} \cdot {d}_{g 2 p}\end{matrix}}{{d}_{gy}^{m}} \qquad ( 11 )$$

$${V}_{y} = \frac{2 π}{λ} \sqrt{{( {n}_{gy}^{m} )}^{2} - {( {n}_{c}^{h} )}^{2}} \frac{{d}_{gy}^{m}}{2} \qquad ( 12 )$$

From the above Expressions (10), (11), (12), a normalized frequency V_{y} in the lamination direction is calculated to be 2.5677, which is greater than π/2, and thus it is found that there are multiple modes. Further, since V_{y}/(π/2) is 1.6347, it is also found that two modes of zeroth and first orders are allowed.

In the structure in which multiple modes are allowed in the lamination direction, a lot of light is confined in the n-side optical guide layer 61 and the p-side optical guide layer 81, so that light less permeates into the AlGaAs cladding layer. Thus, a built-in refractive index difference in the horizontal direction can be reduced, whereby an effect of decreasing the number of built-in allowed modes in the horizontal direction is provided.

In the ridge-type broad-area semiconductor laser device 100 according to embodiment 1, the n-side optical guide layer 61 and the p-side optical guide layer 81 are each composed of two layers. However, each optical guide layer may be composed of only one layer or multiple layers such as three or more layers, and also in such cases, the same configuration as in the case of two layers described in the present disclosure can be applied.

In the ridge-type broad-area semiconductor laser device 100 according to embodiment 1, the layer thickness of the n-side optical guide layer 61 is set to 1150 nm and the layer thickness of the p-side optical guide layer 81 is set to 650 nm. Thus, the position of the quantum well active layer 7 in the lamination direction is displaced to the p-type AlGaAs cladding layer side, and carriers staying in the n-side optical guide layer 61 and the p-side optical guide layer 81 are decreased, whereby slope efficiency reduction due to carrier absorption is prevented.

In the ridge-type broad-area semiconductor laser device 100 according to embodiment 1, the examples in which the length L_{f} of the current confinement region (Cₙ) is 1 mm, 2 mm, and 3 mm and the ridge outer region width Wₒ is 8 μm, 12 μm, and 15 μm, have been shown. However, the present disclosure is not limited thereto.

As described above, in the ridge-type broad-area semiconductor laser device 100 according to embodiment 1, the current non-injection structures, i.e., the current confinement region is provided in a part in the resonator, and the current injection region is provided in the other part of the resonator. Thus, the gains in low-order modes become greater than the gains in high-order modes, so that laser oscillation can be caused in low-order modes and the horizontal divergence angle is narrowed, and as compared to the case where the current non-injection structures are provided over the entire resonator, the electric resistance is reduced, whereby operation voltage is reduced and power conversion efficiency is improved.

### Embodiment 2

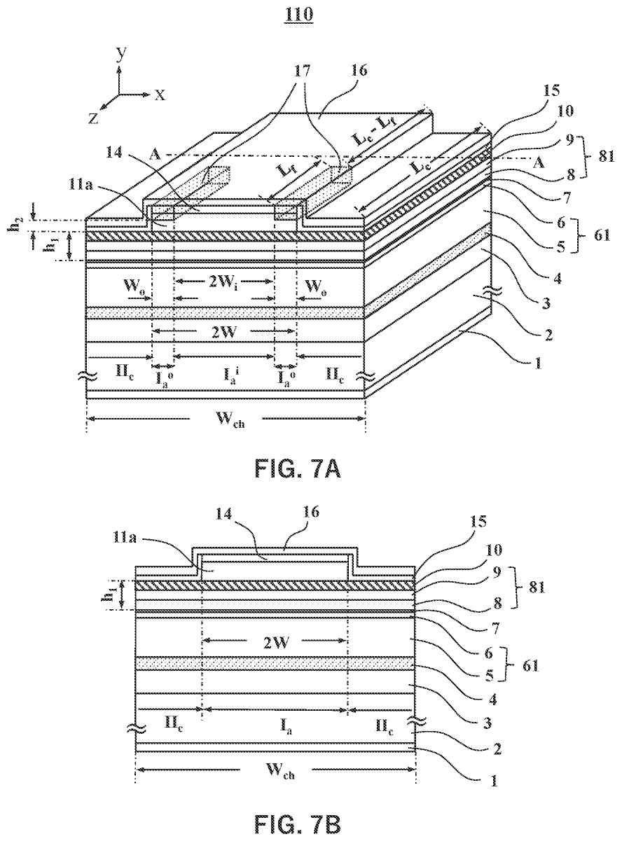

FIG. 7A is a perspective view showing a ridge-type broad-area semiconductor laser device 110 in 975 nm band having a real refractive index distribution according to embodiment 2. FIG. 7B is a sectional view of a current injection region (Cᵢ) in the ridge-type broad-area semiconductor laser device 110, i.e., a sectional view along line A-A in FIG. 7A.

The ridge-type broad-area semiconductor laser device 110 according to embodiment 2 is different from the ridge-type broad-area semiconductor laser device 100 according to embodiment 1 in that the second ESL layer 12 is not provided, a p-type AlGaAs cladding layer formed by a single layer, i.e., a p-type AlGaAs cladding layer 11a (second-conductivity-type cladding layer) having an Al composition ratio of 0.20 and a layer thickness of 1.5 μm, is provided instead of the p-type AlGaAs first cladding layer 11 having an Al composition ratio of 0.20 and a layer thickness of 0.50 μm and the p-type AlGaAs second cladding layer 13 having an Al composition ratio of 0.20 and a layer thickness of 0.96 μm in the ridge-type broad-area semiconductor laser device 100 according to embodiment 1, and proton implanted regions 17 are provided as current non-injection structures. The other layer configurations are the same as those of the ridge-type broad-area semiconductor laser device 100 according to embodiment 1.

A manufacturing method for the ridge-type broad-area semiconductor laser device 110 according to embodiment 2 will be described below.

Above the n-type GaAs substrate 2, the semiconductor layers from the n-type AlGaAs cladding layer 3 to the p-type GaAs contact layer 14 are sequentially crystal-grown by a crystal growth method such as MOCVD.

Next, the ridge inner region (Iₐⁱ) in the current confinement region (Cₙ) having the length L_{f} and the ridge region (Iₐ) in the current injection region (Cᵢ) having the length L_{c}−L_{f} are coated with a resist, protons are ion-implanted to form the proton implanted regions 17, and the resist is removed.

Subsequently, the ridge inner region (Iₐⁱ) and the ridge outer regions (2Iₐ^{o}) in the current confinement region (Cₙ) having the length L_{f} and the ridge region (Iₐ) in the current injection region (Cᵢ) having the length L_{c}−L_{f} are coated with a resist, dry etching is performed until reaching the first ESL layer 10, and the resist is removed. At this stage, the proton implanted regions formed in the cladding regions (II_{c}) are also removed by etching.

The ridge inner region (Iₐⁱ) and the ridge outer regions (2Iₐ^{o}) in the current confinement region (Cₙ) having the length L_{f} and the ridge region (Iₐ) in the current injection region (Cᵢ) having the length L_{c}−L_{f} are coated with a resist, the SiN insulation films 15 are formed, lift-off is performed, and the resist is removed.

Further, the p-type electrode 16 and the n-type electrode 1 are formed on the upper surface side and the lower surface side, respectively.

The ridge outer regions (Iₐ^{o}) in the current confinement region (Cₙ) in embodiment 2 are formed by imparting the semiconductor layer with insulation property through proton implantation, instead of removal by etching and covering with the SiN insulation films 15 as in embodiment 1. Although the second ESL layer 12 is not present in the structure in embodiment 2, the effective refractive index nₐⁱin the ridge inner region (Iₐⁱ) is 3.41773.

The effective refractive index nc in the cladding regions (II_{c}) has the same value 3.41723 in the current confinement region (Cₙ) and the current injection region (Cᵢ), and in a case where the ridge region width 2W (Wₒ=0 μm) is 100 μm, the value v/(π/2) obtained by dividing v in Expression (1) by π/2 is 11.991 and thus twelve modes of zeroth (fundamental) to eleventh orders are allowed.

The effective refractive index nₐ^{o} in the ridge outer regions (Iₐ^{o}) in which protons are ion-implanted is 3.41773 which is the same value as the effective refractive index nₐⁱin the ridge inner region (Iₐⁱ). As an example, if protons are ion-implanted to a depth of 1.0 μm from the p-type GaAs contact layer 14, the distance h₂ from the upper end of the first ESL layer 10 to the lower end of the proton implanted region 17 is 0.7 μm.

If the distance h₂ from the upper end of the first ESL layer 10 to the lower end of the proton implanted region 17 is 0.5 μm and the p-type AlGaAs cladding layer 11a and the p-type GaAs contact layer 14 above the first ESL layer 10 are removed, the effective refractive index nₐ^{o} in the ridge outer regions (Iₐ^{o}) is calculated to be 3.41773 which is the same value as the effective refractive index nₐⁱin the ridge inner region (Iₐⁱ). This shows that there is substantially no light in a region distant in the y direction from the first ESL layer 10 by 0.5 μm or more. This means that the proton implanted region 17 is a region in which there is substantially no light. In the structure in embodiment 2, as described above, the distance h₂ from the upper end of the first ESL layer 10 to the lower end of the proton implanted region 17 is 0.7 μm.

For example, it is assumed that, over the entire resonator length L_{c} (L_{c}=4 mm), protons are ion-implanted in the ridge outer region width Wₒ=12 μm to a depth of 1 μm from the upper surface of the p-type GaAs contact layer 14, to form the proton implanted regions 17, thereby providing the current non-injection structures (distance h₂=0.7 μm).

Current spreads from the lower ends of the proton implanted regions 17 in the ±x directions starting from both ends of the ridge inner region width 2Wᵢ which is the width of the ridge inner region (Iₐⁱ). That is, current spreads in the ±x direction through the distance h₁ (0.73 μm) from the upper end of the quantum well active layer 7 to the upper end of the first ESL layer 10 and the distance h₂ (0.7 μm) from the upper end of the first ESL layer 10 to the lower ends of the proton implanted regions 17, thus reaching the quantum well active layer 7.

As an example, in a case where, in the region

having the length L_{f}=2 mm in the resonator, protons are ion-implanted in the ridge outer region width Wₒ=12 μm to a depth of 1 μm from the surface of the p-type GaAs contact layer, thus forming the current non-injection structures, i.e., a case of providing the current confinement region (Cₙ) having the length L_{f}=2 mm and the ridge outer region width Wₒ=12 μm, current spreads from the lower ends of the proton implanted regions 17 starting from both ends of the ridge inner region width 2Wᵢ of the ridge inner region (Iₐⁱ) and passes through the distance h₂ (0.7 μm) from the lower ends of the proton implanted regions 17 to the upper end of the first ESL layer 10 and the distance h₁ (0.73 μm) from the upper end of the first ESL layer 10 to the upper end of the quantum well active layer 7, thus reaching the quantum well active layer 7.

Meanwhile, in the current injection region (Cᵢ, length: L_{c}−L_{f}=2 mm) which is the other part in the resonator, current spreads from the upper end of the first ESL layer 10 starting from both ends of the ridge region width 2W.

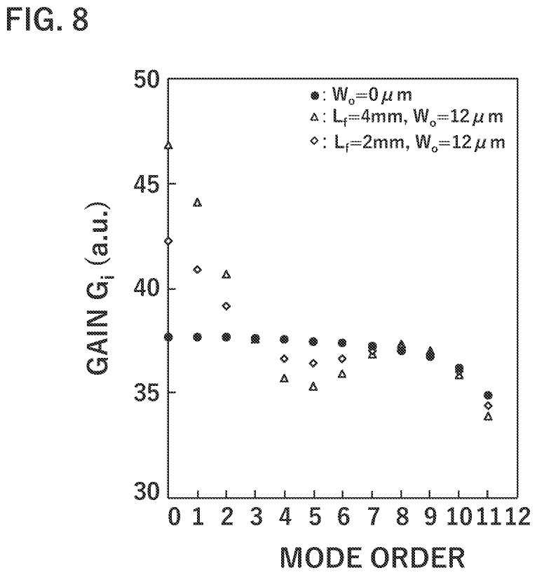

FIG. 8 shows the gain Gᵢ in each mode in the case where there are no current non-injection structures over the entire resonator (Wₒ=0 μm), the case where the current non-injection structures are provided over the entire resonator (L_{f}=L_{c}=4 mm, Wₒ=12 μm), and the case where the current non-injection structures are provided in a part in the resonator (L_{f}=2 mm, Wₒ=12 μm), i.e., the current confinement region (Cₙ) having the length L_{f}=2 mm is provided, by black circle marks, white triangular marks, and rhombus marks, respectively. In the case where there are no current non-injection structures over the entire resonator (Wₒ=0 μm, black circle marks in FIG. 8), it is found that there is almost no gain difference among the modes. In particular, in mode orders not higher than 9, the tendency in which there is no gain difference among the modes is remarkable.

In the case where the current non-injection structures (L_{f}=2 mm, Wₒ=12 μm), i.e., the current confinement region (Cₙ) having the length L_{f}=2 mm is provided in a part in the resonator, gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width is 12 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n) side downward from the quantum well active layer 7 is 0.14 V, and operation current when the beam output is 5 W is 5.0 A. Then, in the case where there are no current non-injection structures (Wₒ=0 μm), the case where the current non-injection structures are provided over the entire resonator (L_{f}=L_{c}=4mm, Wₒ=12 μm), and the case where the current non-injection structures are provided in a part in the resonator (L_{f}=2 mm, Wₒ=12 μm), i.e., the current confinement region (Cₙ) having the length L_{f}=2 mm is provided, operation voltages are calculated to be 1.518 V, 1.551 V, and 1.532 V, respectively, and power conversion efficiencies when the beam output is 5 W are 63.4%, 62.0%, and 62.8%, respectively.

In the case where the current confinement region (Cₙ) as described above is provided in the ridge-type broad-area semiconductor laser device 110 according to embodiment 2, as compared to the case where there are no current non-injection structures over the entire resonator, gain differences among the modes become greater and the gains Gᵢ in low-order modes (zeroth to second orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 110 according to embodiment 2, the current injection area becomes smaller as compared to the case where there is no current confinement region (Cₙ) at all. Thus, in the ridge-type broad-area semiconductor laser device 110 according to embodiment 2, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger in the case where the current confinement region (Cₙ) as described above is provided. This means that the electric resistance is reduced. Thus, an effect that operation voltage is reduced and power conversion efficiency is improved is provided.

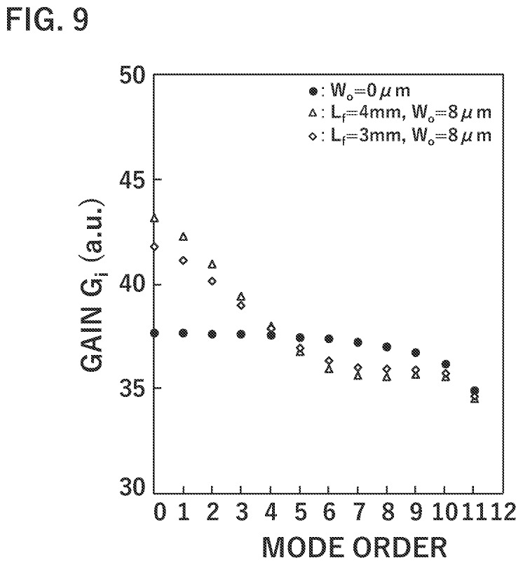

FIG. 9 shows the gain Gᵢ in each mode in the case where the current non-injection structures are provided over the entire resonator (L_{f}=L_{c}=4 mm, Wₒ=8 μm) and the case where the current non-injection structures are provided in a part in the resonator (L_{f}=3 mm, Wₒ=8 μm), i.e., the current confinement region (Cₙ) having the length L_{f}=3 mm is provided, by white triangular marks and rhombus marks, respectively. In addition, for comparison, the gain Gᵢ in each mode in the case where there are no current non-injection structures over the entire resonator (Wₒ=0 μm, black circle marks in FIG. 9) is shown by black circle marks.

In the case where the current non-injection structures (L_{f}=3 mm, Wₒ=8 μm), i.e., the current confinement region (Cₙ) having the length L_{f}=3 mm is provided in a part in the resonator, gain differences arise among the modes and the gains Gᵢ in low-order modes of zeroth to fourth orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 8 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=8 μm) and the case where the current non-injection structures are provided in a part in the resonator (L_{f}=3 mm, Wₒ=8 μm), i.e., the current confinement region (Cₙ) having the length L_{f}=3 mm is provided, operation voltages are calculated to be 1.538 V and 1.532 V, respectively, and power conversion efficiencies when the beam output is 5 W are 62.5% and 62.8%, respectively.

In the case where the current confinement region (Cₙ) as described above is provided in the ridge-type broad-area semiconductor laser device 110 according to embodiment 2, as compared to the case where there are no current non-injection structures over the entire resonator, gain differences among the modes become greater and the gains Gᵢ in low-order modes (zeroth to fourth orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 110 according to embodiment 2, the current injection area becomes smaller as compared to the case where there is no current confinement region (Cₙ) at all. Thus, in the ridge-type broad-area semiconductor laser device 110 according to embodiment 2, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger in the case where the current confinement region (Cₙ) as described above is provided. This means that the electric resistance is reduced. Thus, an effect that operation voltage is reduced and power conversion efficiency is improved is provided.

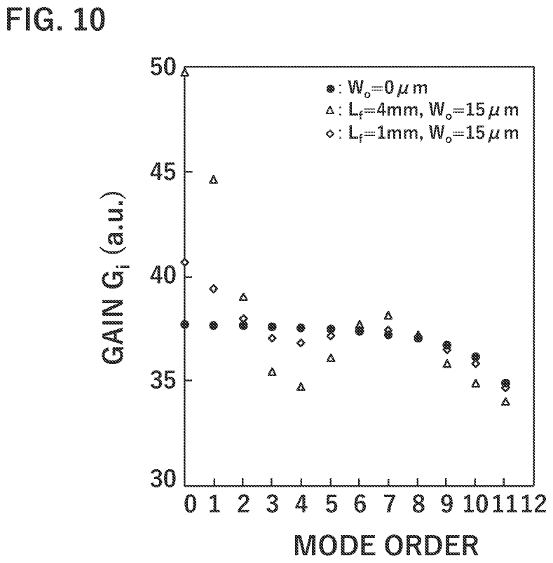

FIG. 10 shows the gain Gᵢ in each mode in the case where the current non-injection structures are provided over the entire resonator (L_{f}=L_{c}=4 mm, Wₒ=15 μm) and the case where the current non-injection structures are provided in a part in the resonator (L_{f}=1mm, Wₒ=15 μm), i.e., the current confinement region (Cₙ) having the length L_{f}=1 mm is provided, by white triangular marks and rhombus marks, respectively. In addition, for comparison, the gain Gᵢ in each mode in the case where there are no current non-injection structures over the entire resonator (Wₒ=0 μm) is shown by black circle marks.

In the case where the current non-injection structures (L_{f}=1 mm, Wₒ=15 μm), i.e., the current confinement region (Cₙ) having the length L_{f}=1 mm is provided in a part in the resonator, gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 15 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity- type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=15 μm) and the case where the current non-injection structures are provided in a part in the resonator (L_{f}=1 mm, Wₒ=15 μm), i.e., the current confinement region (Cₙ) having the length L_{f}=1 mm is provided, operation voltages are calculated to be 1.563 V and 1.526 V, respectively, and power conversion efficiencies when the beam output is 5 W are 61.5% and 63.0%, respectively.

In the case where the current confinement region (Cₙ) as described above is provided in the ridge-type broad-area semiconductor laser device 110 according to embodiment 2, as compared to the case where there are no current non-injection structures over the entire resonator, gain differences among the modes become greater and the gains Gᵢ in low-order modes (zeroth to second orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 110 according to embodiment 2, the current injection area becomes smaller as compared to the case where there is no current confinement region (Cₙ) at all. Thus, as compared to the case where there are no current non-injection structures over the entire resonator, operation voltage becomes higher to a certain extent and power conversion efficiency becomes lower to a certain extent.

Further, the ridge-type broad-area semiconductor laser device 110 according to embodiment 2 provides an effect that operation voltage is reduced and power conversion efficiency is improved, as compared to the case where the current non-injection structures are provided over the entire resonator.

As described above, in the case where the current non-injection structures, i.e., the current confinement region (Cₙ) is provided in a part in the resonator, irrespective of the length of the current confinement region (Cₙ) or the value of the ridge outer region width Wₒ, gain differences can be provided among allowed modes and the gains Gᵢ in low-order modes can be made greater than the gains Gᵢ in high-order modes, as compared to the case where the current confinement region (Cₙ) is not provided. Thus, laser oscillation is reached in low-order modes and the horizontal divergence angle is narrowed. In addition, since loss does not change depending on whether or not the current confinement region (Cₙ) is present, oscillation occurs with a smaller gain Gᵢ and threshold current is reduced.

In the broad-area semiconductor laser device 110 according to the present embodiment 2, the first ESL layer 10 is provided between the p-side second guide layer 9 and the p-type AlGaAs cladding layer 11a. However, the first ESL layer 10 may be provided in the p-type AlGaAs cladding layer 11a. In this case, while the p-type AlGaAs cladding layer 11a on the upper side of the first ESL layer 10 is removed by etching, the p-type AlGaAs cladding layer 11a on the lower side of the first ESL layer 10 is left, thus contributing to spread of current.

Also in the ridge-type broad-area semiconductor laser device 110 according to embodiment 2, as in the structure according to embodiment 1, uₙ<uₚ is satisfied, and an optical intensity distribution in the y direction, i.e., the lamination direction, is displaced to the n-type GaAs substrate 2 side, thus forming a structure in which the number of built-in allowed modes in the x direction, i.e., the ridge-width direction, is decreased. If the number of built-in allowed modes is decreased in advance, gain differences can be easily provided among the allowed modes and thus there is an advantage in terms of oscillation in low-order modes.

As a method for decreasing the number of built-in allowed modes by displacing the optical intensity distribution to the n-type GaAs substrate 2 side, the layer thickness of the p-type AlGaAs low-refractive-index layer 10 may be increased, the refractive index nₗₚ of the p-type AlGaAs low-refractive-index layer 10 may be reduced, or the refractive index n_{cn} of the n-type AlGaAs cladding layer 3 may be made greater than the refractive index n_{cp} of the p-type AlGaAs cladding layer 11a, for example.

In the ridge-type broad-area semiconductor laser device 110 according to embodiment 2, since proton implantation is used as means for imparting the semiconductor layer with insulation property, an etching process is not needed, thus providing an effect of decreasing the number of manufacturing steps and also facilitating the manufacturing of the ridge-type broad-area semiconductor laser device, as compared to the structure in embodiment 1.

The distance h₁ from the upper end of the first ESL layer 10 to the current non-injection structure, i.e., the lower end of the proton implanted region 17, is 0.70 μm. In a region where the distance hi is 0.70 μm, there is almost no light, so that there is no influence from scattering due to crystal breakage caused by proton implantation and loss due to the scattering, and there is no reliability reduction due to crystal defect.

As described above, in the ridge-type broad-area semiconductor laser device 110 according to embodiment 2, the current non-injection structures, i.e., the current confinement region is provided in a part in the resonator, the current injection region is provided in the other part of the resonator, and the current non-injection structures are formed by providing the proton implanted regions. Thus, the gains in low-order modes become greater than the gains in high-order modes, so that laser oscillation can be caused in low-order modes and the horizontal divergence angle is narrowed, and as compared to the case where the current non-injection structures are provided over the entire resonator, the electric resistance is reduced, whereby operation voltage is reduced and power conversion efficiency is improved. Further, increase in scattering loss due to crystal defect is suppressed, whereby high reliability can be achieved.

### Embodiment 3

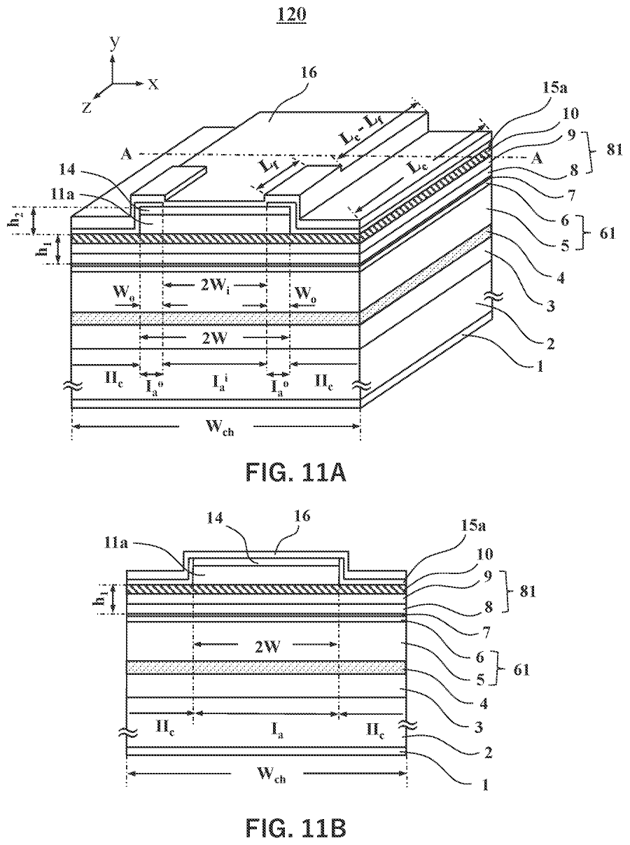

FIG. 11A is a perspective view showing a ridge-type broad-area semiconductor laser device 120 in 975 nm band having a real refractive index distribution according to embodiment 3. FIG. 11B is a sectional view of a current injection region (Cᵢ) in the ridge-type broad-area semiconductor laser device 120, i.e., a sectional view along line A-A in FIG. 11A.

The ridge-type broad-area semiconductor laser device 120 according to embodiment 3 is different from the ridge-type broad-area semiconductor laser device 100 according to embodiment 1 in that the second ESL layer 12 is not provided, a p-type AlGaAs cladding layer formed by a single layer, i.e., a p-type AlGaAs cladding layer 11a (second-conductivity-type cladding layer) having an Al composition ratio of 0.20 and a layer thickness of 1.5 μm, is provided instead of the p-type AlGaAs first cladding layer 11 having an Al composition ratio of 0.20 and a layer thickness of 0.50 μm and the p-type AlGaAs second cladding layer 13 having an Al composition ratio of 0.20 and a layer thickness of 0.96 μm in the ridge-type broad-area semiconductor laser device 100 according to embodiment 1, and the ridge outer regions (Iₐ^{o}) in the current confinement region (Cₙ) in embodiment 3 are formed by providing SiN insulation films 15a at parts of the upper surface of the p-type GaAs contact layer 14, instead of removal by etching and covering with the insulation films. The other layer configurations are the same as those of the ridge-type broad-area semiconductor laser device 100 according to embodiment 1.

A manufacturing method for the ridge-type broad-area semiconductor laser device 120 according to embodiment 3 will be described below.

Above the n-type GaAs substrate 2, the semiconductor layers from the n-type AlGaAs cladding layer 3 to the p-type GaAs contact layer 14 are sequentially crystal-grown by a crystal growth method such as MOCVD.

Next, the ridge inner region (Iₐⁱ) and the ridge outer regions (2Iₐ^{o}) in the current confinement region (Cₙ) and the ridge region (Iₐ) in the current injection region (Cᵢ) are coated with a resist, dry etching is performed until reaching the first ESL layer 10, and the resist is removed.

Subsequently, the ridge inner region (Iₐⁱ) in the current confinement region (Cₙ) having the length L_{f} and the ridge region (Iₐ) in the current injection region (Cᵢ) having the length L_{c}−L_{f} are coated with a resist, the SiN insulation films 15a are formed, lift-off is performed, and the resist is removed.

Further, the p-type electrode 16 and the n-type electrode 1 are formed on the upper surface side and the lower surface side, respectively.

Although the second ESL layer 12 is not present in the ridge-type broad-area semiconductor laser device 120 according to embodiment 3, the effective refractive index nai in the ridge inner region (Iₐ) is 3.41773. The effective refractive index n_{c} in the cladding regions (II_{c}) has the same value 3.41723 in the current confinement region (Cₙ) and the current injection region (Cᵢ), and in a case where the ridge region width 2W (Wₒ=0 μm) is 100 μm, the value v/(π/2) obtained by dividing v in Expression (1) by π/2 is 11.991 and thus twelve modes of zeroth (fundamental) to eleventh orders are allowed. Since current spreads from the upper surface of the p-type GaAs contact layer 14, the distance h₂ becomes 1.7 μm.

For example, it is assumed that, over the entire resonator length L_{c} (L_{c}=4 mm), the current non-injection structures are formed in the ridge outer region width Wₒ=12 μm (distance h₂=1.7 μm). Current spreads from the upper surface of the p-type GaAs contact layer 14 also in the ±x directions starting from both ends of the ridge inner region width 2Wᵢ of the ridge inner region (Iₐⁱ). That is, current spreads in the tx directions through the distance h₁ (0.73 μm) from the upper end of the quantum well active layer 7 to the upper end of the first ESL layer 10 and the distance h₂ (1.7 μm) from the upper end of the first ESL layer 10 to the upper surface of the p-type GaAs contact layer 14, thus reaching the quantum well active layer 7.

As an example, in a case where, in the region having the length L_{f}=3 mm in the resonator, the current non-injection structures are provided by the SiN insulation films 15a over the ridge outer region width Wₒ=12 μm to form the current confinement region (Cₙ) having the length L_{f}=3 mm, current spreads from the upper surface of the p-type GaAs contact layer 14 starting from both ends of the ridge inner region width 2Wᵢ of the ridge inner region (Iₐⁱ) and passes through the distance h₂ (1.7 μm) from the upper end of the p-type GaAs contact layer 14 to the upper end of the first ESL layer 10 and the distance h₁ (0.73 μm) from the upper end of the first ESL layer 10 to the upper end of the quantum well active layer 7, thus reaching the quantum well active layer 7.

Meanwhile, in the current injection region (Cᵢ, length: L_{c}−L_{f}=1 mm) which is the other part in the resonator, current spreads from the upper end of the first ESL layer 10 starting from both ends of the ridge region width 2W.

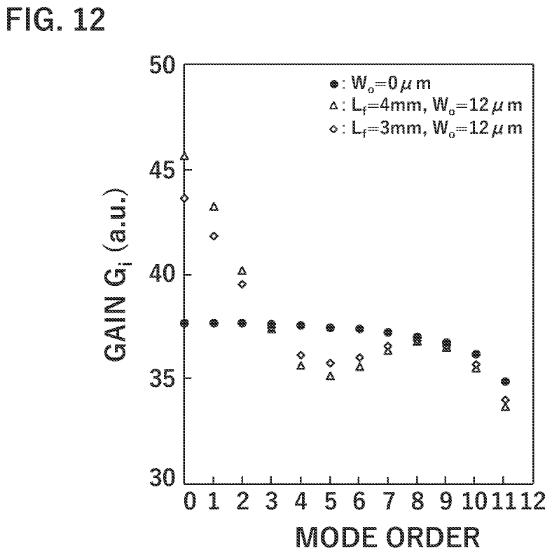

FIG. 12 shows the gain Gᵢ in each mode in the case where there are no current non-injection structures over the entire resonator (Wₒ=0 μm), the case where the current non-injection structures are provided over the entire resonator (L_{f}=L_{c}=4mm, Wₒ=12 μm), and the case where the current non-injection structures are provided in a part in the resonator (L_{f}=3 mm, Wₒ=12 μm), i.e., the current confinement region (Cₙ) having the length L_{f}=3 mm is provided, by black circle marks, white triangular marks, and rhombus marks, respectively. In the case where there are no current non-injection structures over the entire resonator, it is found that there is almost no gain difference among the modes. In particular, in mode orders not higher than 9, the tendency in which there is no gain difference among the modes is remarkable.

In the case where the current non-injection structures (L_{f}=3 mm, Wₒ=12 μm), i.e., the current confinement region (Cₙ) having the length L_{f}=3 mm is provided in a part in the resonator, gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 12 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n) side downward from the quantum well active layer 7 is 0.14 V, and operation current when the beam output is 5 W is 5.0 A. Then, in the case where there are no current non-injection structures (Wₒ=0 μm), the case where the current non-injection structures are provided over the entire resonator (L_{f}=L_{c}=4 mm, Wₒ=12 μm), and the case where the current non-injection structures are provided in a part in the resonator (L_{f}=3 mm, Wₒ=12 μm), i.e., the current confinement region (Cₙ) having the length L_{f}=3 mm is provided, operation voltages are calculated to be 1.518 V, 1.548 V, and 1.539 V, respectively, and power conversion efficiencies when the beam output is 5 W are 63.4%, 62.1%, and 62.5%, respectively.

In the case where the current confinement region (Cₙ) as described above is provided in the ridge-type broad-area semiconductor laser device 120 according to embodiment 3, as compared to the case where there are no current non-injection structures over the entire resonator, gain differences among the modes become greater and the gains Gᵢ in low-order modes (zeroth to second orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 120 according to embodiment 3, the current injection area becomes smaller as compared to the case where there is no current confinement region (Cₙ) at all. Thus, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger. This means that the electric resistance is reduced. Thus, an effect that operation voltage is reduced and power conversion efficiency is improved is provided.

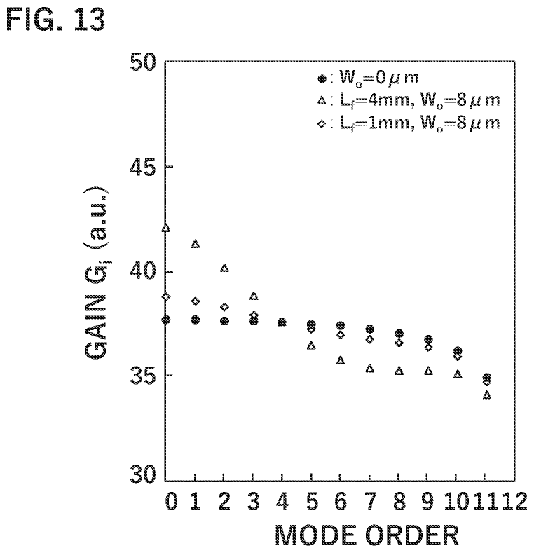

FIG. 13 shows the gain Gᵢ in each mode in the case where the current non-injection structures are provided over the entire resonator (L_{f}=L_{c}=4 mm, Wₒ=8 μm) and the case where the current non-injection structures are provided in a part in the resonator (L_{f}=1 mm, Wₒ=8 μm), i.e., the current confinement region (Cₙ) having the length L_{f}=1 mm is provided, by white triangular marks and rhombus marks, respectively. In addition, for comparison, the gain Gᵢ in each mode in the case where there are no current non-injection structures over the entire resonator (Wₒ=0 μm) is shown by black circle marks.

In the case where the current non-injection structures (L_{f}=1 mm, Wₒ=8 μm), i.e., the current confinement region (Cₙ) having the length L_{f}=1 mm is provided in a part in the resonator, gain differences arise among the modes and the gains Gᵢ in low-order modes of zeroth to third orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 8 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=8 μm) and the case where the current non-injection structures are provided in a part in the resonator (L_{f}=1 mm, Wₒ=8 μm), i.e., the current confinement region (Cₙ) having the length L_{f}=1 mm is provided, operation voltages are calculated to be 1.535 V and 1.522 V, respectively, and power conversion efficiencies when the beam output is 5 W are 62.6% and 63.2%, respectively.

In the case where the current confinement region (Cₙ) as described above is provided in the ridge-type broad-area semiconductor laser device 120 according to embodiment 3, as compared to the case where there are no current non-injection structures over the entire resonator, gain differences among the modes become greater and the gains Gᵢ in low-order modes (zeroth to third orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 120 according to embodiment 3, the current injection area becomes smaller as compared to the case where there is no current confinement region (Cₙ) at all. Thus, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger. This means that the electric resistance is reduced. Thus, an effect that operation voltage is reduced and power conversion efficiency is improved is provided.

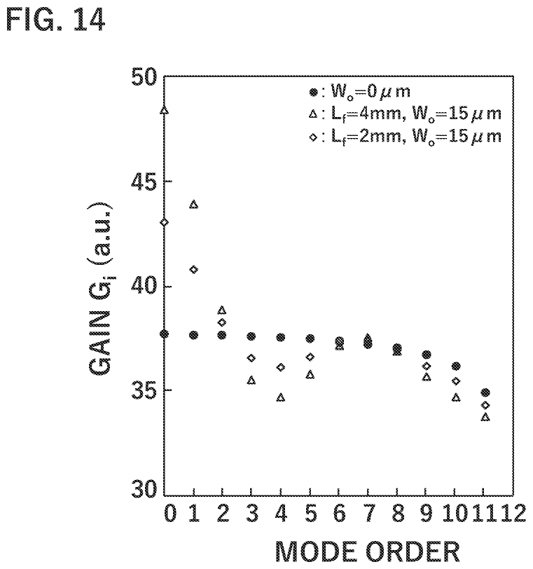

FIG. 14 shows the gain Gᵢ in each mode in the case where the current non-injection structures are provided over the entire resonator (L_{f}=L_{c}=4 mm, Wₒ=15 μm) and the case where the current non-injection structures are provided in a part in the resonator (L_{f}=2 mm, Wₒ=15 μm), i.e., the current confinement region (Cₙ) having the length L_{f}=2 mm is provided, by white triangular marks and rhombus marks, respectively. In addition, for comparison, the gain Gᵢ in each mode in the case where there are no current non-injection structures over the entire resonator (Wₒ=0 μm) is shown by black circle marks.

In the case where the current non-injection structures (L_{f}=2 mm, Wₒ=8 μm), i.e., the current confinement region (Cₙ) having the length L_{f}=2 mm is provided in a part in the resonator, gain differences arise among the modes and the gains Gᵢ in low-order modes of zeroth to second orders become greater than the gains Gᵢ in other high-order modes.

In general, the semiconductor laser device performs oscillation in a mode having a great gain Gᵢ. Therefore, a low-order mode is selected, so that the beam divergence angle is narrowed. In the case where the current non-injection structures of which the ridge outer region width Wₒ is 8 μm are provided over the entire resonator length L_{c} (L_{c}=4 mm), gain differences among the modes further increase, so that oscillation is performed in a lower-order mode and the horizontal divergence angle is further narrowed.

Here, it is assumed that turn-on voltage of p-n junction is 1.335 V, voltage drop on the first-conductivity-type (n-type) side downward from the quantum well active layer 7 is 0.14 V, and operation current when the beam output is 5 W is 5.0 A. Then, in the case where the current non-injection structures are provided over the entire resonator (L_{f}=L_{c}=4 mm, Wₒ=15 μm) and the case where the current non-injection structures are provided in a part in the resonator (L_{f}=2 mm, Wₒ=15 μm), i.e., the current confinement region (Cₙ) having the length L_{f}=2 mm is provided, operation voltages are calculated to be 1.560 V and 1.535 V, respectively, and power conversion efficiencies when the beam output is 5 W are 61.6% and 62.6%, respectively.

In the case where the current confinement region (Cₙ) as described above is provided in the ridge-type broad-area semiconductor laser device 120 according to embodiment 3, as compared to the case where there are no current non-injection structures over the entire resonator, gain differences among the modes become greater and the gains Gᵢ in low-order modes (zeroth to third orders) become greater than the gains Gᵢ in other high-order modes. Thus, laser oscillation occurs in low-order modes and the horizontal divergence angle is narrowed.

In addition, in the case where the current confinement region (Cₙ) as described above is provided in the ridge-type broad-area semiconductor laser device 120 according to embodiment 3, the current injection area becomes smaller as compared to the case where there is no current confinement region (Cₙ) at all. Thus, as compared to the case where there are no current non-injection structures over the entire resonator, operation voltage becomes higher to a certain extent and power conversion efficiency becomes lower to a certain extent.

On the other hand, as compared to the case where the current non-injection structures are provided over the entire resonator, the current injection area becomes larger. This means that the electric resistance is reduced. Thus, an effect that operation voltage is reduced and power conversion efficiency is improved is provided.

As described above, in the case where the current non-injection structures, i.e., the current confinement region (Cₙ) is provided in a part in the resonator, irrespective of the length of the current confinement region (Cₙ) or the value of the ridge outer region width Wo, gain differences can be provided among allowed modes and the gains Gᵢ in low-order modes can be made greater than the gains Gᵢ in high-order modes, as compared to the case where the current confinement region (Cₙ) is not provided. Thus, laser oscillation is reached in low-order modes and the horizontal divergence angle is narrowed. In addition, since loss does not change depending on whether or not the current confinement region (Cₙ) is present, oscillation occurs with a smaller gain Gᵢ and threshold current is reduced.

Further, the ridge-type broad-area semiconductor laser device 120 according to embodiment 3 provides an effect that operation voltage is reduced and power conversion efficiency is improved, as compared to the case where the current non-injection structures are provided over the entire resonator.

Also in the ridge-type broad-area semiconductor laser device 120 according to embodiment 3, as in the structure according to embodiment 1, uₙ<uₚ is satisfied, and an optical intensity distribution in the y direction, i.e., the lamination direction, is displaced to the n-type GaAs substrate 2 side, thus forming a structure in which the number of built-in allowed modes in the x direction, i.e., the ridge-width direction is decreased. If the number of built-in allowed modes is decreased in advance, gain differences can be easily provided among the allowed modes and thus there is an advantage in terms of oscillation in low-order modes.

In the broad-area semiconductor laser device 120 according to the present embodiment 3, the first ESL layer 10 is provided between the p-side second guide layer 9 and the p-type AlGaAs cladding layer 11a. However, the first ESL layer 10 may be provided in the p-type AlGaAs cladding layer 11a. In this case, while the p-type AlGaAs cladding layer 11a on the upper side of the first ESL layer 10 is removed by etching, the p-type AlGaAs cladding layer 11a on the lower side of the first ESL layer 10 is left, thus contributing to spread of current.

As a method for decreasing the number of built-in allowed modes by displacing the optical intensity distribution to the n-type GaAs substrate 2 side, the layer thickness of the p-type AlGaAs low-refractive-index layer 10 may be increased, the refractive index nₗₚ of the p-type AlGaAs low-refractive-index layer 10 may be reduced, or the refractive index n_{cn} of the n-type AlGaAs cladding layer 3 may be made greater than the refractive index n_{cp} of the p-type AlGaAs cladding layer 11a, for example.

In the ridge-type broad-area semiconductor laser device 120 according to embodiment 3, the current non-injection structures are formed by providing the SiN insulation films 15a at parts of the upper surface of the p-type GaAs contact layer 14. Therefore, for example, the number of processing steps in etching is decreased and a proton implantation process is not performed, and thus there is an advantage that manufacturing is greatly facilitated as compared to the structures in embodiments 1 and 2.

As described above, in the ridge-type broad-area semiconductor laser device 110 according to embodiment 3, the current non-injection structures, i.e., the current confinement region is provided in a part in the resonator, the current injection region is provided in the other part of the resonator, and the current non-injection structures are formed by providing the SiN insulation films 15a at parts of the upper surface of the p-type GaAs contact layer 14. Thus, the gains in low-order modes become greater than the gains in high-order modes, so that laser oscillation can be caused in low-order modes and the horizontal divergence angle is narrowed, and as compared to the case where the current non-injection structures are provided over the entire resonator, the electric resistance is reduced, whereby operation voltage is reduced and power conversion efficiency is improved. Further, increase in scattering loss due to crystal defect is suppressed, whereby high reliability can be achieved. In addition, the manufacturing is greatly facilitated.

### Embodiment 4

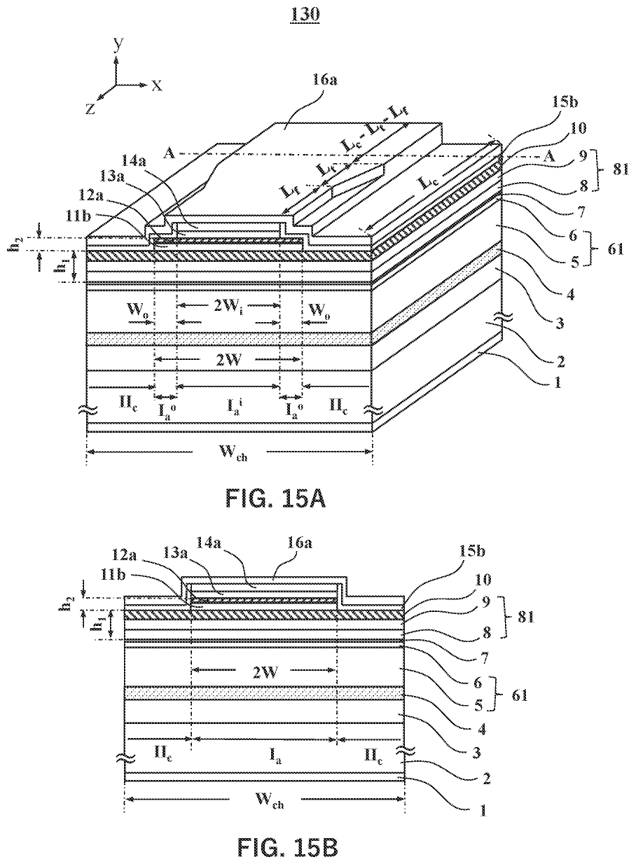

FIG. 15A is a perspective view showing a ridge-type broad-area semiconductor laser device 130 in 975 nm band having a real refractive index distribution according to embodiment 4. FIG. 15B is a sectional view of a current injection region (Cᵢ) in the ridge-type broad-area semiconductor laser device 130, i.e., a sectional view along line A-A in FIG. 15A.

The ridge-type broad-area semiconductor laser device 130 according to embodiment 4 includes a p-type AlGaAs first cladding layer 11b having an Al composition ratio of 0.20 and a layer thickness of 0.50 μm, a p-type AlGaAs second etching stop layer 12a (second ESL layer 12a) having an Al composition ratio of 0.55 and a layer thickness of 40 nm, a p-type AlGaAs second cladding layer 13a having an Al composition ratio of 0.20 and a layer thickness of 0.96 μm, a p-type GaAs contact layer 14a having a layer thickness of 0.2 μm, SiN insulation films 15b having a film thickness of 0.2 μm, and a p-type electrode 16a.

The structure of the ridge-type broad-area semiconductor laser device 130 according to embodiment 4 is different from that of the ridge-type broad-area semiconductor laser device 100 according to embodiment 1 shown in FIG. 3 in that a taper-shaped current confinement region (Cₜ) having a length Lt is provided between the current confinement region (Cₙ) having the length L_{f} and the current injection region (Cᵢ). Hereinafter, the taper-shaped current confinement region (Cₜ) may be referred to as taper region (Cₜ).

The ridge region width in the ridge-width direction of each current non-injection structure in the taper-shaped current confinement region (Cₜ) coincides with the ridge outer region width Wo of the ridge outer region (Iₐ^{o}) at the end contacting with the current confinement region (Cₙ), and decreases toward the current injection region (Cᵢ) from the current confinement region (Cₙ), so as to become zero at a part contacting with the current injection region (Cᵢ).

A manufacturing method for the ridge-type broad-area semiconductor laser device 130 according to embodiment 4 will be described below.

The manufacturing method is the same as that for the structure in embodiment 1 except that the ridge inner region (Iₐⁱ) in the current confinement region (Cₙ) having the length Lf, the ridge inner region (Iₐⁱ) in the taper-shaped current confinement region (Cₜ) having the length Lₜ, and the ridge region (Iₐ) in the current injection region (Cᵢ) having a length L_{c}−(L_{f}+Lₜ), are coated with a resist, and dry etching is performed until reaching the second ESL layer 12a.

Even when etching is performed until reaching the second ESL layer 12a, the effective refractive index at the etching part is the same value as the effective refractive index nₐⁱin the ridge inner region (Iₐⁱ), and the number of modes allowed in the structure having the taper-shaped current confinement region (Cₜ) is the same as that in the case where the taper region is not present.

In the case where the taper-shaped current confinement region (Cₜ) is provided, a gain distribution in the ridge-width direction (x direction) that a beam making a round trip in the resonator feels is gradually enlarged or reduced, thus providing an effect of suppressing non-linearity (kink) of beam output-current characteristics (P-I characteristics) of the semiconductor laser device. The length Lₜ of the taper-shaped current confinement region (Cₜ) is any value that satisfies 0<Lₜ<L_{c}.

As described above, in the ridge-type broad-area semiconductor laser device 130 according to embodiment 4, the taper-shaped current confinement region (Cₜ) having the length Lₜ is provided between the current confinement region (Cₙ) having the length L_{f} and the current injection region (Cᵢ). Thus, in addition to the effects provided by the ridge-type broad-area semiconductor laser device 100 according to embodiment 1, an effect of suppressing non-linearity (kink) of beam output-current characteristics (P-I characteristics) is provided.

### Embodiment 5

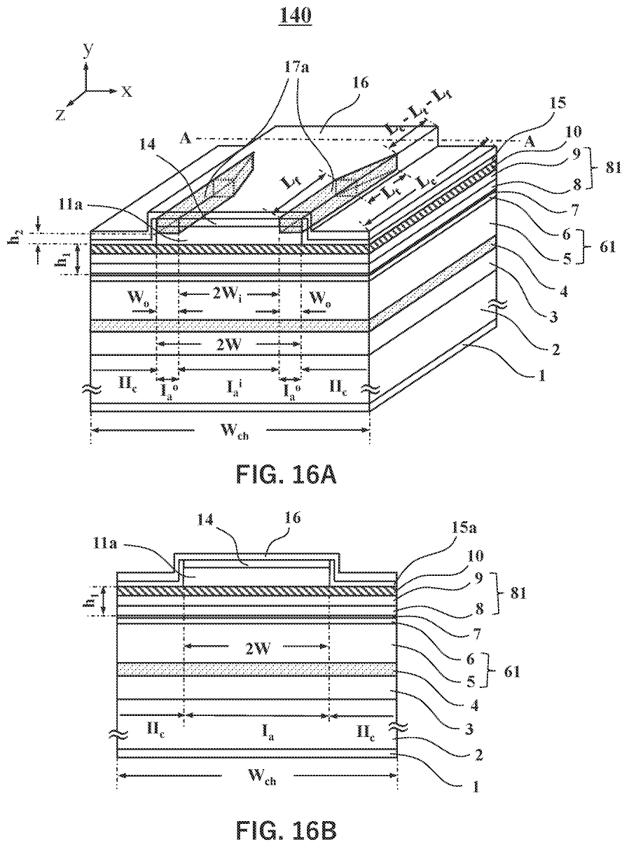

FIG. 16A is a perspective view showing a ridge-type broad-area semiconductor laser device 140 in 975 nm band having a real refractive index distribution according to embodiment 5. FIG. 16B is a sectional view of a current injection region (Cᵢ) in the ridge-type broad-area semiconductor laser device 140, i.e., a sectional view along line A-A in FIG. 16A.

In FIG. 16A, 17a denotes proton implanted regions. A difference from FIG. 7 showing the structure in embodiment 2 is that a taper-shaped current confinement region (Cₜ) having a length Lₜ is provided between the current confinement region (Cₙ) having the length L_{f} and the current injection region (Cᵢ).

A manufacturing method for the ridge-type broad-area semiconductor laser device 140 according to embodiment 5 is the same as that for the structure in embodiment 2 except that the ridge inner region (Iₐⁱ) in the current confinement region (Cₙ) having the length Lf, the ridge inner region (Iₐⁱ) in the taper-shaped current confinement region (Cₜ) having the length Lₜ, and the ridge region (Iₐ) in the current injection region (Cᵢ) having the length L_{c}−(L_{f}+Lₜ), are coated with a resist, and protons are ion-implanted to form the proton implanted regions 17a.

A depth in which protons are ion-implanted is such a depth that, even in a case where the proton-implantation part is removed by etching, the effective refractive index at this part is substantially the same as the effective refractive index nₐⁱin the ridge inner region (Iₐⁱ), and this part is a region where there is substantially no light. Therefore, slope efficiency reduction by increase in optical loss due to scattering or reliability reduction due to crystal defect is not caused.

In the case where the taper-shaped current confinement region (Cₜ) is provided, a gain distribution in the ridge-width direction (x direction) that a beam making a round trip in the resonator feels is gradually enlarged or reduced, thus providing an effect of suppressing non-linearity (kink) of beam output-current characteristics (P-I characteristics) of the semiconductor laser device. The length Lₜ of the taper-shaped current confinement region (Cₜ) is any value that satisfies 0<Lₜ<L_{c}.

As described above, in the ridge-type broad-area semiconductor laser device 140 according to embodiment 5, the taper-shaped current confinement region (Cₜ) having the length Lₜ is provided between the current confinement region (Cₙ) having the length L_{f} and the current injection region (Cᵢ). Thus, in addition to the effects provided by the ridge-type broad-area semiconductor laser device 110 according to embodiment 2, an effect of suppressing non-linearity (kink) of beam output-current characteristics (P-I characteristics) is provided.

### Embodiment 6

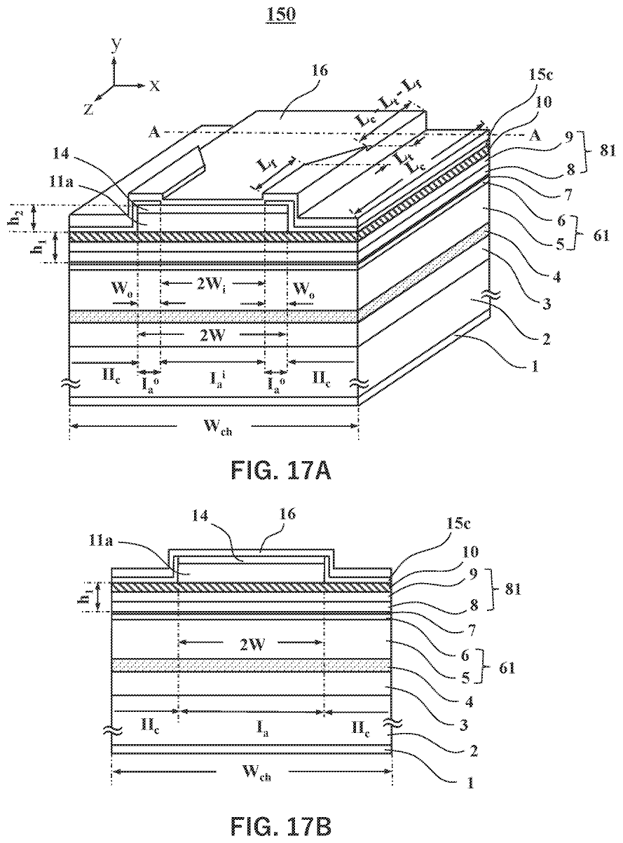

FIG. 17A is a perspective view showing a ridge-type broad-area semiconductor laser device 150 in 975 nm band having a real refractive index distribution according to embodiment 6. FIG. 17B is a sectional view of a current injection region (Cᵢ) in the ridge-type broad-area semiconductor laser device 150, i.e., a sectional view along line A-A in FIG. 17A.

In FIG. 17A, 15c denotes SiN insulation films having a film thickness of 0.2 μm. A difference from FIG. 11 showing the structure in embodiment 3 is that a taper-shaped current confinement region (Cₜ) having a length Lₜ is provided between the current confinement region (Cₙ) having the length L_{f} and the current injection region (Cᵢ).

A manufacturing method for the ridge-type broad-area semiconductor laser device 150 according to embodiment 6 is the same as that for the structure in embodiment 3 except that the ridge inner region (Iₐⁱ) in the current confinement region (Cₙ) having the length Lf, the ridge inner region (Iₐⁱ) in the taper-shaped current confinement region (Cₜ) having the length Lₜ, and the ridge region (Iₐ) in the current injection region (Cᵢ) having the length L_{c}−(L_{f}+Lₜ), are coated with a resist, the SiN insulation films 15c are formed, and lift-off is performed.

The current non-injection structures are formed by the SiN insulation films 15c provided on the upper surface of the p-type GaAs contact layer 14. Therefore, the effective refractive index of the current non-injection structures in the taper region (Cₜ) and the ridge outer regions (Iₐ^{o}) is the same as the effective refractive index nₐⁱin the ridge inner region (Iₐⁱ), and irrespective of whether or not the current non-injection structures are present, the number of allowed modes is the same.

In the case where the taper-shaped current confinement region (Cₜ) is provided, a gain distribution in the ridge-width direction (x direction) that a beam making a round trip in the resonator feels is gradually enlarged or reduced, thus providing an effect of suppressing non-linearity (kink) of beam output-current characteristics (P-I characteristics) of the semiconductor laser device. The length Lₜ of the taper-shaped current confinement region (Cₜ) is any value that satisfies 0<Lₜ<L_{c}.

As described above, in the ridge-type broad-area semiconductor laser device 150 according to embodiment 6, the taper-shaped current confinement region (Cₜ) having the length Lₜ is provided between the current confinement region (Cₙ) having the length L_{f} and the current injection region (Cᵢ) having the length L_{c}−(L_{f} +Lₜ). Thus, in addition to the effects provided by the ridge-type broad-area semiconductor laser device 120 according to embodiment 3, an effect of suppressing non-linearity (kink) of beam output-current characteristics (P-I characteristics) is provided.

In the ridge-type broad-area semiconductor laser devices according to embodiments 1 to 6, the current non-injection structures are provided in contact with an end surface, but may be provided at any position in the resonator. Normally, a high-output semiconductor laser device emits a lot of light from the front end surface, with the front end surface having a low reflectance and the rear end surface having a high reflectance. As disclosed in Non-Patent Document 5, the current density is higher on the low-reflectance side than on the high-reflectance side in the resonator.

In a case of desiring to achieve high power conversion efficiency while suppressing operation voltage increase, the current non-injection structures may be provided on the high-reflectance side where the current density is low. On the other hand, in a case of desiring to provide great gain differences among allowed modes, the current non-injection structure may be provided on the low-reflectance side where the current density is high. In the present disclosure, the semiconductor laser

device having an oscillation wavelength of 975 nm has been described as an example. However, as a matter of course, the wavelength is not limited thereto. The same effects can be provided also in a case of using a semiconductor laser device of a GaN-based type in 400 nm band, a GaInP-based type in 600 nm band, or an InGaAsP-based type in 1550 nm band, for example.

In the present disclosure, the n-type substrate is used and the ridge structure is formed on the p-type contact layer side. Conversely, a p-type substrate may be used and the ridge structure may be formed on the n-type contact layer side, whereby the same effects are obtained.

In the present disclosure, the broad-area semiconductor laser device in which the ridge region width 2W is 100 μm has been described as an example. However, without limitation thereto, the ridge region width 2W may be any value as long as a high-order mode of a first order or higher is allowed in the horizontal direction.

In the present disclosure, the broad-area semiconductor laser device in which the resonator length L_{c} is 4 mm has been described as an example. However, without limitation thereto, the resonator length L_{c} may be any value.

Embodiments 1 to 6 have exemplified the ridge-type broad-area semiconductor laser devices configured such that the number of allowed horizontal-transverse modes is decreased and gain differences are provided among the allowed horizontal-transverse modes, whereby oscillation is performed in low-order modes and the horizontal divergence angle is narrowed. However, without limitation thereto, the same effects are provided even in a case of a normal ridge-type broad-area semiconductor laser device in which the number of horizontal transverse modes is not decreased.

In embodiments 1 to 6, the effective refractive index nₐ^{o}in the ridge outer regions (Iₐ^{o}) and the effective refractive index nₐⁱin the ridge inner region (Iₐⁱ) are equal to each other. However, they may be substantially the same, as described in embodiment 1.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type electrode (first conductivity type electrode)
2 n-type GaAs substrate
3 n-type AlGaAs cladding layer
4 n-type AlGaAs low-refractive-index layer
5 n-side AlGaAs second optical guide layer
6 n-side AlGaAs first optical guide layer
7 InGaAs quantum well active layer
8 p-side AlGaAs first optical guide layer
9 p-side AlGaAs second optical guide layer
10 p-type AlGaAs first ESL layer (p-type AlGaAs low-refractive-index layer)
11 p-type AlGaAs first cladding layer
11a p-type AlGaAs cladding layer
11b p-type AlGaAs first cladding layer
12, 12a p-type AlGaAs second etching stop layer (second ESL layer)
13, 13a p-type AlGaAs second cladding layer
14, 14a p-type GaAs contact layer
15 15, 15a, 15b, 15c SiN insulation film
16, 16a p-type electrode (second conductivity type electrode)
17, 17a proton implanted region
61 n-side optical guide layer (first-conductivity-
20 type-side optical guide layer)
81 p-side optical guide layer (second-conductivity-type-side optical guide layer)
100, 110, 120, 130, 140, 150 ridge-type broad-area semiconductor laser device
101 active layer
102 guide layer
103 first etching stop layer (first ESL layer)
104 p-type first cladding layer
105 second etching stop layer (second ESL layer)
106 p-type second cladding layer
107 p-type contact layer

1. A semiconductor laser device comprising:
a first-conductivity-type semiconductor substrate;
a first-conductivity-type cladding layer, a first-conductivity-type-side optical guide layer, an active layer, a second-conductivity-type-side optical guide layer, a second-conductivity-type cladding layer, and a second-conductivity-type contact layer, which are sequentially laminated above the first-conductivity-type semiconductor substrate; and
a resonator having a length L_{c} and formed of a front end surface and a rear end surface to allow a round trip of a laser beam therebetween, wherein
an oscillation wavelength is λ,
the resonator includes a current confinement region having a length L_{f} and a current injection region having a length L_{c}−Lf,
the current confinement region is composed of
a ridge inner region of which a width is 2Wᵢ and an effective refractive index is nₐ,
ridge outer regions which are provided on both sides of the ridge inner region and of which a width is Wₒ and an effective refractive index is nₐ^{o}, the ridge outer regions having current non-injection structures, and
cladding regions which are provided on both sides of the ridge outer regions and in which the second-conductivity-type contact layer and at least a part of the second-conductivity-type cladding layer are removed and an effective refractive index is n_{c},
an average refractive index nₐ^{e} of the ridge inner region and the ridge outer region is represented by the following expression:
nₐ^{e}=(nₐⁱ·Wᵢ+nₐ^{o}·Wₒ)/(Wᵢ+Wₒ),
the following relationship is satisfied:
$$\frac{2 π}{λ} \sqrt{{( {n}_{a}^{e} )}^{2} - {n}_{c}^{2}} ( {W}_{i} + {W}_{o} ) > \frac{π}{2} ,$$
a number of modes allowed in a ridge-width direction in the current confinement region is m, m being an integer not less than 2,
the width Wₒ of the ridge outer region is greater than a distance from a lower end of each current non-injection structure to the active layer,
the current injection region is composed of
a ridge region of which a width in the ridge-width direction is 2W and an effective refractive index is nₐ which is a real number, and
the cladding regions provided on both sides of the ridge region,
a number of modes allowed in the ridge-width direction in the current injection region is m which is the same as the number of modes allowed in the current confinement region, and
the length L_{f} of the current confinement region is greater than zero and smaller than the length Le of the resonator.

2. A semiconductor laser device comprising:
a first-conductivity-type semiconductor substrate;
a first-conductivity-type cladding layer, a first-conductivity-type-side optical guide layer, an active layer, a second-conductivity-type-side optical guide layer, a second-conductivity-type cladding layer, and a second-conductivity-type contact layer, which are sequentially laminated above the first-conductivity-type semiconductor substrate; and
a resonator having a length L_{c} and formed of a front end surface and a rear end surface to allow a round trip of a laser beam therebetween, wherein
an oscillation wavelength is 2,
the resonator includes a current confinement region having a length Lf, a current injection region having a length L_{c}−(L_{f} +Lₜ), and a taper region having a length Lₜ and provided between the current confinement region and the current injection region current confinement region,
the current confinement region is composed of
a ridge inner region of which a width is 2Wᵢ and an effective refractive index is nₐ ,
ridge outer regions which are provided on both sides of the ridge inner region and of which a width is Wₒ and an effective refractive index is nₐ , the ridge outer regions having current non-injection structures, and
cladding regions which are provided on both sides of the ridge outer regions and in which the second-conductivity-type contact layer and at least a part of the second-conductivity-type cladding layer are removed and an effective refractive index is nc,
an average refractive index nₐ^{e} of the ridge inner region and the ridge outer region is represented by the following expression:
nₐ^{e}=(nₐⁱ·Wᵢ+nₐ^{o}·Wₒ)/(Wᵢ+Wₒ),
the following relationship is satisfied:
$$\frac{2 π}{λ} \sqrt{{( {n}_{a}^{e} )}^{2} - {n}_{c}^{2}} ( {W}_{i} + {W}_{o} ) > \frac{π}{2} ,$$
a number of modes allowed in a ridge-width direction in the current confinement region is m, m being an integer not less than 2,
the width Wₒ of the ridge outer region is greater than a distance from a lower end of each current non-injection structure to the active layer,
the current injection region is composed of
a ridge region of which a width in the ridge-width direction is 2W and an effective refractive index is nₐ which is a real number, and
the cladding regions provided on outer sides of the ridge region,
a number of modes allowed in the ridge-width direction in the current injection region is m which is the same as the number of modes allowed in the current confinement region,
the length L_{f} of the current confinement region is greater than zero,
the length Lₜ of the taper region is greater than zero, and
a width in the ridge-width direction of each current non-injection structure in the taper region coincides with the width Wₒ of the ridge outer region at an end contacting with the current confinement region, and decreases toward the current injection region from the current confinement region, so as to become zero at a part contacting with the current injection region.

3. The semiconductor laser device according to claim 1, wherein
the second-conductivity-type cladding layer is composed of a second-conductivity-type first cladding layer and a second-conductivity-type second cladding layer, and
the current non-injection structures in the ridge outer regions have insulation films coating exposed surfaces on which the second-conductivity-type contact layer and at least a part of the second-conductivity-type second cladding layer are removed in the ridge outer regions.

4. The semiconductor laser device according to claim 1, wherein
the current non-injection structures in the ridge outer regions are formed of proton implanted regions.

5. The semiconductor laser device according to claim 1, wherein
the current non-injection structures in the ridge outer regions are formed of insulation films respectively coating parts of surfaces on both ends in the ridge-width direction of the second-conductivity-type contact layer in the ridge outer regions.

6. The semiconductor laser device according to claim 1, wherein
a refractive index of the first-conductivity-type cladding layer is n_{cn} and a refractive index of the second-conductivity-type cladding layer is n_{cp},
a first-conductivity-type low-refractive-index layer having a thickness din and a refractive index nₗₙ smaller than the refractive index n_{cn} of the first-conductivity-type cladding layer is provided between the first-conductivity-type-side optical guide layer and the first-conductivity-type cladding layer or in the first-conductivity-type cladding layer,
a second-conductivity-type low-refractive-index layer having a layer thickness dₗₚ and a refractive index nₗₚ smaller than the refractive index of the second-conductivity-type cladding layer is provided between the second-conductivity-type-side optical guide layer and the second-conductivity-type cladding layer or in the second-conductivity-type cladding layer, and
the following relationship is satisfied:
$$\frac{2 π}{λ} \sqrt{{n}_{cp}^{2} - {n}_{ip}^{2}} \frac{{d}_{ip}}{2} > \frac{2 π}{λ} \sqrt{{n}_{cn}^{2} - {n}_{in}^{2}} \frac{{d}_{in}}{2} .$$

7. The semiconductor laser device according to claim 1, wherein
a layer thickness of the first-conductivity-type-side optical guide layer is greater than a layer thickness of the second-conductivity-type-side optical guide layer.

8. The semiconductor laser device according to claim 1, wherein
where a sum of layer thicknesses of the first-conductivity-type-side optical guide layer, the active layer, and the second-conductivity-type-side optical guide layer is dgym, an average refractive index of the first-conductivity-type-side optical guide layer, the active layer, and the second-conductivity-type-side optical guide layer is n_{gy}^{m}, and a greater one of a refractive index n_{cn} of the first-conductivity-type cladding layer and a refractive index n_{cp} of the second-conductivity-type cladding layer is n_{c}^{h}, a normalized frequency V_{y} in a lamination direction is represented by the following expression:
$${V}_{y} = \frac{2 π}{λ} \sqrt{{( {n}_{gy}^{m} )}^{2} - {( {n}_{c}^{h} )}^{2}} \frac{{d}_{gy}^{m}}{2} ,$$
and
the normalized frequency V_{y} is greater than π/2.

9. The semiconductor laser device according to claim 1, wherein
a refractive index n_{cn} of the first-conductivity-type cladding layer is greater than a refractive index n_{cp} of the second-conductivity-type cladding layer.

10. The semiconductor laser device according to claim 2, wherein
the second-conductivity-type cladding layer is composed of a second-conductivity-type first cladding layer and a second-conductivity-type second cladding layer, and
the current non-injection structures in the ridge outer regions have insulation films coating exposed surfaces on which the second-conductivity-type contact layer and at least a part of the second-conductivity-type second cladding layer are removed in the ridge outer regions.

11. The semiconductor laser device according to claim 2, wherein
the current non-injection structures in the ridge outer regions are formed of proton implanted regions.

12. The semiconductor laser device according to claim 2, wherein
the current non-injection structures in the ridge outer regions are formed of insulation films respectively coating parts of surfaces on both ends in the ridge-width direction of the second-conductivity-type contact layer in the ridge outer regions.

13. The semiconductor laser device according to claim 2, wherein
a refractive index of the first-conductivity-type cladding layer is n_{cn} and a refractive index of the second-conductivity-type cladding layer is n_{cp},
a first-conductivity-type low-refractive-index layer having a thickness dₗₙ and a refractive index nin smaller than the refractive index n_{cn} of the first-conductivity-type cladding layer is provided between the first-conductivity-type-side optical guide layer and the first-conductivity-type cladding layer or in the first-conductivity-type cladding layer,
a second-conductivity-type low-refractive-index layer having a layer thickness dₗₚ and a refractive index nₗₚ smaller than the refractive index of the second-conductivity-type cladding layer is provided between the second-conductivity-type-side optical guide layer and the second-conductivity-type cladding layer or in the second-conductivity-type cladding layer, and
the following relationship is satisfied:
$$\frac{2 π}{λ} \sqrt{{n}_{cp}^{2} - {n}_{lp}^{2}} \frac{{d}_{lp}}{2} > \frac{2 π}{λ} \sqrt{{n}_{cn}^{2} - {n}_{ln}^{2}} \frac{{d}_{ln}}{2} .$$

14. The semiconductor laser device according to claim 2, wherein
a layer thickness of the first-conductivity-type-side optical guide layer is greater than a layer thickness of the second-conductivity-type-side optical guide layer.

15. The semiconductor laser device according to claim 2, wherein
where a sum of layer thicknesses of the first-conductivity-type-side optical guide layer, the active layer, and the second-conductivity-type-side optical guide layer is d_{gy}^{m}, an average refractive index of the first-conductivity-type-side optical guide layer, the active layer, and the second-conductivity-type-side optical guide layer is n_{gy}^{m}, and a greater one of a refractive index n_{cn} of the first-conductivity-type cladding layer and a refractive index n_{cp} of the second-conductivity-type cladding layer is n_{c}^{h}, a normalized frequency V_{y} in a lamination direction is represented by the following expression:
$${V}_{y} = \frac{2 π}{λ} \sqrt{{( {n}_{gy}^{m} )}^{2} - {( {n}_{c}^{h} )}^{2}} \frac{{d}_{gy}^{m}}{2} ,$$
and
the normalized frequency V_{y} is greater than π/2.

16. The semiconductor laser device according to claim 2, wherein
a refractive index n_{cn} of the first-conductivity-type cladding layer is greater than a refractive index n_{cp} of the second-conductivity-type cladding layer.
